(19) United States
(12) Patent Application Publication
(10) Pub. No.: US 2017/0133500 A1
(43) Pub. Date: May 11, 2017

(54) NITRIDE SEMICONDUCTOR DEVICE

(71) Applicant: PANASONIC INTELLECTUAL PROPERTY MANAGEMENT CO., LTD., Osaka (JP)

(72) Inventors: Ryuuji ETOU, Niigata (JP); Takeshi HARADA, Toyama (JP); Masakazu HAMADA, Toyama (JP); Tamotsu SHIBATA, Toyama (JP)

(21) Appl. No.: 15/415,663

(22) Filed: Jan. 25, 2017

Related U.S. Application Data
(63) Continuation of application No. PCT/JP2015/003709, filed on Jul. 24, 2015.

(30) Foreign Application Priority Data
Jul. 29, 2014 (JP) 2014-153514

(51) Int. Cl. H01L 29/778; H01L 29/808; H01L 29/20; H01L 29/04; H01L 21/283; H01L 29/66; H01L 27/098; H01L 29/812

(52) U.S. Cl. CPC H01L 29/7787; H01L 27/098; H01L 29/808; H01L 29/812; H01L 29/045; H01L 21/283; H01L 29/66462; H01L 29/2003

(57) ABSTRACT

A nitride semiconductor device according to the present disclosure includes a substrate, a p-type GaN layer formed on a main surface of the substrate and made of AlₓIn_{y}Ga_{1-x-y}N containing p-type impurities, where 0≦X<1, 0≦Y<1, and a Ti film formed on the p-type GaN layer. The Ti film is in a coherent or metamorphic state with respect to the p-type GaN layer.

### CROSS REFERENCE TO RELATED APPLICATIONS

This application is a U.S. continuation application of PCT International Patent Application Number PCT/JP2015/003709 filed on Jul. 24, 2015, claiming the benefit of priority of Japanese Patent Application Number 2014-153514 filed on Jul. 29, 2014, the entire contents of which are hereby incorporated by reference.

### BACKGROUND

1. Technical Field

The present disclosure relates to a nitride semiconductor device using a p-type nitride semiconductor.

2. Description of the Related Art

Power switching field effect transistors (FETs) need to achieve low on-state resistance in order to reduce power loss. Additionally, the interruption of current flow at zero bias, i.e., normally off characteristics, are dispensable from the viewpoint of safety.

One example of technology that achieves low on-state resistance and normally off characteristics of FETs using gallium nitride (GaN) is using a p-type nitride semiconductor layer as a gate and forming a gate recess in the lower part of the p-type nitride semiconductor layer (see Embodiment 1 of Japanese Unexamined Patent Application Publication 2009-200395 (Patent Literature 1)). This structure can reduce the concentration of a two-dimensional electron gas in a channel below the gate, thus achieving FETs with normally off characteristics and low on-state resistance.

Meanwhile, the p-type nitride semiconductor layer has electrically high resistance, and therefore it is necessary, in order to increase the speed of switching, to reduce the resistance of the gate as a whole by stacking the p-type nitride semiconductor layer and a metal line layer on top of each other. Here, there is demand for low resistance contact between the p-type nitride semiconductor layer and the metal line layer, in addition to a low resistance of the metal line layer itself. The metal line layer also needs to achieve high reliability so that it can be used under hostile environments (with high temperatures and high current) for power switching applications.

For establishment of contact with the p-type nitride semiconductor layer, for example, a method has been reported in which an electrode made of titanium (Ti) and platinum (Pt) is arranged on the surface of the p-type nitride semiconductor layer (see Embodiment 1 of Japanese Unexamined Patent Application Publication 2000-252230 (Patent Literature 2)). With this method, ohmic characteristics are obtained as a result of Ti on the p-type nitride semiconductor layer adsorbing oxygen on the p-type nitride semiconductor layer so that oxygen is removed from the interface of the contact.

However, such conventional nitride semiconductor devices that establish contact by arranging precious metals such as Ti and Pt on the p-type nitride semiconductor layer will not be able to sufficiently reduce the resistance at the contact between the p-type nitride semiconductor layer and the metal line layer and therefore cannot increase the speed of switching.

The nitride semiconductor devices disclosed in the related art documents have mentioned nothing about the method for achieving high reliability so that the devices can be used under hostile environments (with high temperatures and high current) for power switching applications.

In light of the above problems, the present disclosure aims to provide a power switching nitride semiconductor device that achieves high-speed switching by reducing the resistance at the contact between the p-type nitride semiconductor layer and the metal line layer.

### SUMMARY

In order to solve the above-described problems, a nitride semiconductor device according to one aspect of the present disclosure includes a substrate, a semiconductor layer formed on a main surface of the substrate and made of AlₓIn_{y}Ga_{1-x-y}N containing a p-type impurity, where 0≦X<1 and 0≦Y<1, and a titanium (Ti) layer formed on the semiconductor layer. The Ti layer is in a coherent or metamorphic state with respect to the semiconductor layer.

A (0002) crystal plane of the Ti layer may be parallel to and oriented in a same direction as a (0002) crystal plane of the semiconductor layer.

A (10-10) crystal plane of the Ti layer may be parallel to and oriented in a same direction as a (10-10) crystal plane of the semiconductor layer.

The Ti layer may have a thickness of 5 nm or more.

The nitride semiconductor device may further include a metal line layer formed on the Ti layer and made primarily of aluminum. A portion of the Ti layer that is within a fixed distance from an interface between the semiconductor layer and the Ti layer may not be alloyed with the metal line layer.

The fixed distance may be 5 nm or more.

A (111) crystal plane of the metal line layer may be parallel to and oriented in a same direction as a (0002) crystal plane of the Ti layer.

A (220) crystal plane of the metal line layer may be parallel to and oriented in a same direction as a (10-10) crystal plane of the Ti layer.

The Ti layer may have a thickness of 60 nm or less.

The nitride semiconductor device may further includes a titanium nitride (TiN) layer between the Ti layer and the metal line layer.

The TiN layer may have a thickness of 20 nm or more.

A total thickness of the Ti layer and the TiN layer may be 60 nm or less.

The nitride semiconductor device may further includes an insulating layer between the semiconductor layer and the Ti layer. The insulating layer may have a through opening, and the Ti layer may be in contact with the semiconductor layer at a lower surface of the opening.

The opening may have an open lower surface, and an open upper surface that has a larger opening area than the open lower surface. An acute angle formed by a side wall of the opening and the semiconductor layer may be 45 degrees or less.

The nitride semiconductor device may further includes a channel layer formed on the substrate and made of a nitride semiconductor, a barrier layer formed on the channel layer and made of a nitride semiconductor having a larger band gap than the channel layer, a gate electrode formed on a lower surface of the channel layer, and a source electrode and a drain electrode that are formed on each side of the gate electrode and spaced from the gate electrode. The semiconductor layer may be used as the gate electrode.

The nitride semiconductor device may further include a metal line layer formed on the Ti layer and made primarily of copper. A portion of the Ti layer that is within a fixed distance from an interface between the semiconductor layer and the Ti layer may not be alloyed with the metal line layer.

A (111) crystal plane of the metal line layer may be parallel to and oriented in a same direction as a (0002) crystal plane of the Ti layer.

A (220) crystal plane of the metal line layer may be parallel to and oriented in a same direction as a (10-10) crystal plane of the Ti layer.

The nitride semiconductor device may further include a titanium nitride layer between the Ti layer and the metal line layer.

The nitride semiconductor device may further include an insulating layer between the semiconductor layer and the Ti layer. The insulating layer may have a through opening, and the Ti layer may be in contact with the semiconductor layer at a lower surface of the opening.

The nitride semiconductor device according to the present disclosure can reduce the resistance at the contact between the p-type nitride semiconductor layer and the metal line layer. Thus, the present disclosure provides a power switching nitride semiconductor device capable of high-speed switching.

### BRIEF DESCRIPTION OF DRAWINGS

These and other objects, advantages and features of the disclosure will become apparent from the following description thereof taken in conjunction with the accompanying drawings that illustrate a specific embodiment of the present disclosure.

FIG. 1 is a cross-sectional view of a nitride semiconductor device according to Embodiment 1;

FIG. 2A is a cross-sectional view illustrating a nitride semiconductor device manufacturing method according to Embodiment 1;

FIG. 2B is a cross-sectional view illustrating the nitride semiconductor device manufacturing method according to Embodiment 1;

FIG. 2C is a cross-sectional view illustrating the nitride semiconductor device manufacturing method according to Embodiment 1;

FIG. 2D is a cross-sectional view of the nitride semiconductor device manufacturing method according to Embodiment 1;

FIG. 3A is a cross-sectional view illustrating the nitride semiconductor device manufacturing method according to Embodiment 1;

FIG. 3B is a cross-sectional view illustrating the nitride semiconductor device manufacturing method according to Embodiment 1;

FIG. 3C is a cross-sectional view illustrating the nitride semiconductor device manufacturing method according to Embodiment 1;

FIG. 4A is a cross-sectional view illustrating the nitride semiconductor device manufacturing method according to Embodiment 1;

FIG. 4B is a cross-sectional view illustrating the nitride semiconductor device manufacturing method according to Embodiment 1;

FIG. 4C is a cross-sectional view illustrating the nitride semiconductor device manufacturing method according to Embodiment 1;

FIG. 5 illustrates a band structure when Ti and p-type GaN are independent of each other;

FIG. 6 is a comprehensive diagram illustrating a mechanism for improving contact characteristics at a Ti/p-type GaN interface;

FIG. 7A illustrates a structure at the Ti/p-type GaN interface;

FIG. 7B illustrates a structure at the Ti/p-type GaN interface;

FIG. 8 illustrates X-ray diffraction (XRD) spectra obtained by in-plane θ-2θ measurement;

FIG. 9 illustrates XRD spectra obtained by in-plane θ-2θ measurement;

FIG. 10A illustrates (10-10) planes at the Ti/p-type GaN interface;

FIG. 10B illustrates (11-20) planes at the Ti/p-type GaN interface;

FIG. 10C illustrates (0002) planes at the Ti/p-type GaN interface;

FIG. 11 illustrates waveforms obtained by in-plane rocking curve measurement;

FIG. 12 is an enlarged view of the waveforms obtained by in-plane rocking curve measurement;

FIG. 13A is a cross-sectional view illustrating a structure obtained from XRD measurement results for a thick Ti film;

FIG. 13B is a cross-sectional view illustrating a structure obtained from XRD measurement results for a thin Ti film;

FIG. 14 is a cross-sectional view of a nitride semiconductor device according to Embodiment 2;

FIG. 15A is a cross-sectional view illustrating a nitride semiconductor device manufacturing method according to Embodiment 2;

FIG. 15B is a cross-sectional view illustrating the nitride semiconductor device manufacturing method according to Embodiment 2;

FIG. 15C is a cross-sectional view illustrating the nitride semiconductor device manufacturing method according to Embodiment 2;

FIG. 15D is a cross-sectional view illustrating the nitride semiconductor device manufacturing method according to Embodiment 2;

FIG. 16A is a cross-sectional view illustrating the nitride semiconductor device manufacturing method according to Embodiment 2;

FIG. 16B is a cross-sectional view illustrating the nitride semiconductor device manufacturing method according to Embodiment 2;

FIG. 16C is a cross-sectional view illustrating the nitride semiconductor device manufacturing method according to Embodiment 2.

FIG. 17A is a cross-sectional view illustrating the nitride semiconductor device manufacturing method according to Embodiment 2;

FIG. 17B is a cross-sectional view illustrating the nitride semiconductor device manufacturing method according to Embodiment 2;

FIG. 17C is a cross-sectional view illustrating the nitride semiconductor device manufacturing method according to Embodiment 2;

FIG. 18 illustrates XRD spectra obtained by out-of-plane θ-2θ measurement;

FIG. 19A illustrates waveforms obtained by out-of-plane rocking curve measurement;

FIG. 19B illustrates waveforms obtained by out-of-plane rocking curve measurement;

FIG. 20A illustrates a scanning ion microscopy (SIM) image when ion beams are applied perpendicularly to a sample surface;

FIG. 20B illustrates an SIM image when ion beams are applied perpendicularly to a sample surface;

FIG. 21 illustrates an XRD spectrum obtained by in-plane θ-2θ measurement;

FIG. 22 illustrates a waveform obtained by in-plane rocking curve measurement;

FIG. 23 illustrates a reciprocal lattice map obtained by capturing reciprocal lattice points in a (0002) plane of a p-type GaN layer and a (111) plane of an Al film for Sample A in Table 2 by the same measurement;

FIG. 24 is a cross-sectional view of a nitride semiconductor device according to Embodiment 3;

FIG. 25A is a cross-sectional view illustrating a nitride semiconductor device manufacturing method according to Embodiment 3;

FIG. 25B is a cross-sectional view illustrating the nitride semiconductor device manufacturing method according to Embodiment 3;

FIG. 25C is a cross-sectional view illustrating the nitride semiconductor device manufacturing method according to Embodiment 3;

FIG. 25D is a cross-sectional view illustrating the nitride semiconductor device manufacturing method according to Embodiment 3;

FIG. 26A is a cross-sectional view illustrating the nitride semiconductor device manufacturing method according to Embodiment 3;

FIG. 26B is a cross-sectional view illustrating the nitride semiconductor device manufacturing method according to Embodiment 3;

FIG. 26C is a cross-sectional view illustrating the nitride semiconductor device manufacturing method according to Embodiment 3;

FIG. 27A is a cross-sectional view illustrating the nitride semiconductor device manufacturing method according to Embodiment 3;

FIG. 27B is a cross-sectional view illustrating the nitride semiconductor device manufacturing method according to Embodiment 3;

FIG. 27C is a cross-sectional view illustrating the nitride semiconductor device manufacturing method according to Embodiment 3;

FIG. 28 illustrates an XRD spectrum obtained by out-of-plane θ-2θ measurement;

FIG. 29A illustrates waveforms obtained by out-of-plane rocking curve measurement;

FIG. 29B illustrates a waveform obtained by out-of-plane rocking curve measurement;

FIG. 30 illustrates an XRD spectrum obtained by in-plane θ-2θ measurement;

FIG. 31 illustrates a waveform obtained by in-plane rocking curve measurement;

FIG. 32 is a cross-sectional view of a nitride semiconductor device according to Embodiment 4;

FIG. 33A is a cross-sectional view illustrating a nitride semiconductor device manufacturing method according to Embodiment 4;

FIG. 33B is a cross-sectional view illustrating the nitride semiconductor device manufacturing method according to Embodiment 4;

FIG. 33C is a cross-sectional view illustrating the nitride semiconductor device manufacturing method according to Embodiment 4;

FIG. 33D is a cross-sectional view illustrating the nitride semiconductor device manufacturing method according to Embodiment 4;

FIG. 34A is a cross-sectional view illustrating the nitride semiconductor device manufacturing method according to Embodiment 4;

FIG. 34B is a cross-sectional view illustrating the nitride semiconductor device manufacturing method according to Embodiment 4;

FIG. 34C is a cross-sectional view illustrating the nitride semiconductor device manufacturing method according to Embodiment 4;

FIG. 35A is a cross-sectional view illustrating the nitride semiconductor device manufacturing method according to Embodiment 4;

FIG. 35B is a cross-sectional view illustrating the nitride semiconductor device manufacturing method according to Embodiment 4; and

FIG. 35C is a cross-sectional view illustrating the nitride semiconductor device manufacturing method according to Embodiment 4.

### DETAILED DESCRIPTION OF THE EMBODIMENTS

The following describes nitride semiconductor devices according to embodiments of the present disclosure with reference to the drawings. Each embodiment described below shows merely one specific example of the present disclosure. Thus, numerical values, shapes, materials, constituent elements, arrangement and connection of constituent elements, manufacturing steps, a sequence of manufacturing steps, and so on given in the following embodiments are mere examples, and do not intend to limit the present disclosure. Among constituent elements described in the following embodiments, those that are not recited in any of the independent claims, which represent the broadest concepts of the present disclosure, are described as optional constituent elements. The sizes of constituent elements and the ratios of the sizes in the drawings are not strictly proportional to actual sizes and actual ratios of the sizes.

### Embodiment 1

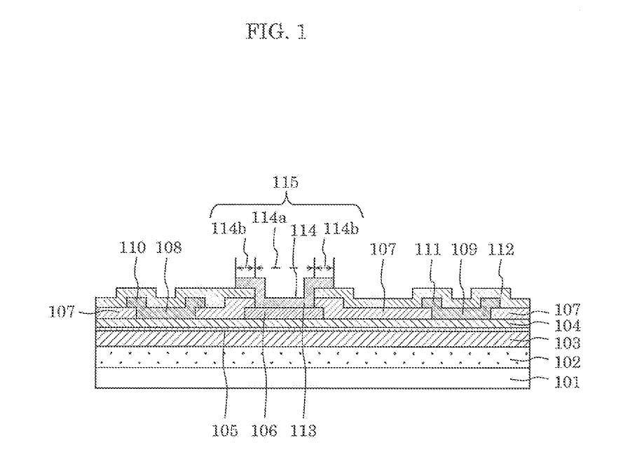

FIG. 1 is a cross-sectional view of a nitride semiconductor device according to Embodiment 1 of the present disclosure. As illustrated in FIG. 1, the nitride semiconductor device according to the present embodiment includes, for example, substrate 101 made of silicon (Si), buffer layer 102 having a thickness of 2 μm and a stacked structure of a plurality of layers including aluminum nitride (AlN) and aluminum gallium nitride (AlGaN), undoped (i-type) GaN layer 103 having a thickness of 2 μm, and i-type AlGaN layer 104 having a thickness of 25 nm and an aluminum (Al) composition ratio of 15%, in such a manner that buffer layer 102, i-type GaN layer 103, and i-type AlGaN layer 104 are formed on substrate 101. Two dimensional electron gas 105 is generated at the heterointerface between i-type AlGaN layer 104 and i-type GaN layer 103. The term “undoped (i-type)” as used herein means that the layer is not intentionally doped with impurities during epitaxial growth.

The nitride semiconductor device according to the present embodiment also includes p-type GaN layer 106 having a thickness of 200 nm and being processed in a predetermined shape on the surface of i-type AlGaN layer 104. Here, p-type GaN layer 106 is doped with magnesium (Mg) at a concentration of approximately 5×10¹⁹ cm⁻³. However, most Mg is neutralized as a result of forming Mg—H complexes with hydrogen (H), and only approximately 1% of Mg, e.g., approximately 5×10¹⁷ cm⁻³, functions as acceptor ions.

The nitride semiconductor device according to the present embodiment further includes silicon nitride (SiN) film 107 on the surfaces of i-type AlGaN layer 104 and p-type GaN layer 106. The Si content in SiN film 107 is approximately 50%. This ratio is higher than the stoichiometric mixture ratio (43%).

SiN film 107 has source opening 108 and drain opening 109 that reach i-type AlGaN layer 104 and in which source electrode 110 and drain electrode 111 are respectively provided to cover the openings. Source electrode 110 and drain electrode 111 have a structure in which a Ti film and an Al film are sequentially stacked on top of each other, and establish electrical contact with two-dimensional electron gas 105 generated at the heterointerface between i-type AlGaN layer 104 and i-type GaN layer 103.

Another SiN film 112 is formed on the surfaces of SiN film 107, source electrode 110, and drain electrode 111. As in the case of SiN film 107, the Si content in SiN film 112 is approximately 50%.

SiN films 107 and 112 have gate opening 113 that reaches p-type GaN layer 106, and gate electrode 115 is formed to cover gate opening 113. Gate electrode 115 includes Ti film 114a that is in contact with p-type GaN layer 106, and Ti film 114b that is in contact with SiN film 112. Ti films 114a and 114b both have a thickness of 10 nm. Ti film 114a, which is in contact with p-type GaN layer 106, is grown coherently or metamorphically on p-type GaN layer 106. Note that the definitions of the terms “coherent growth” and “metamorphic growth” will be described later in detail.

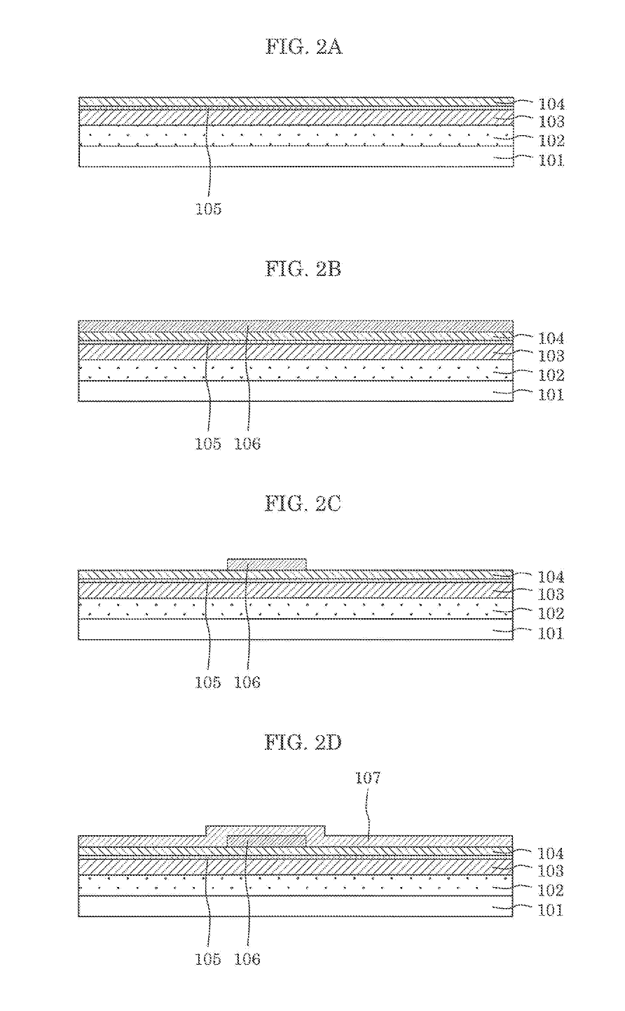

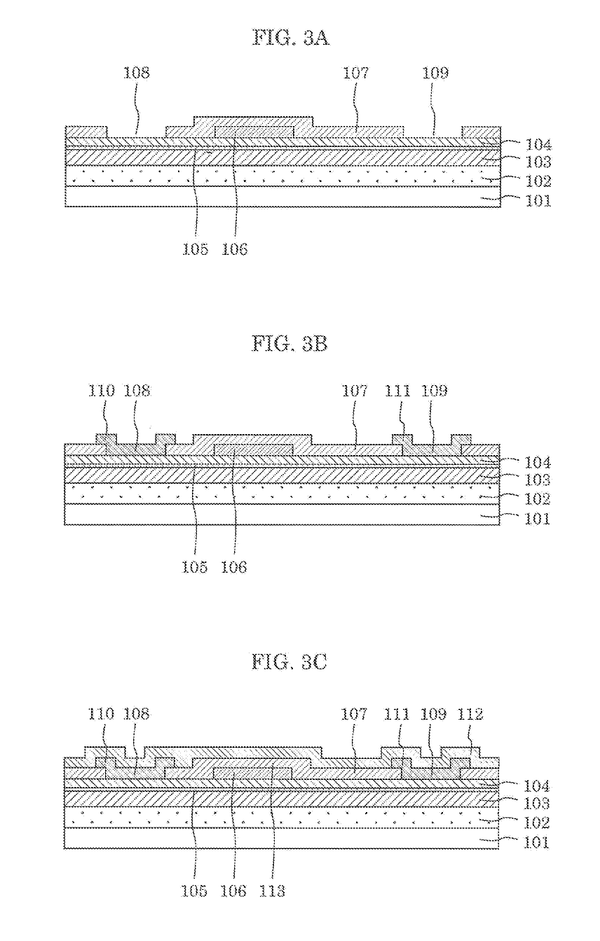

Hereinafter, a nitride semiconductor device manufacturing method according to Embodiment 1 will be described with reference to FIGS. 2A to 2D, 3A to 3C, and 4A to 4C.

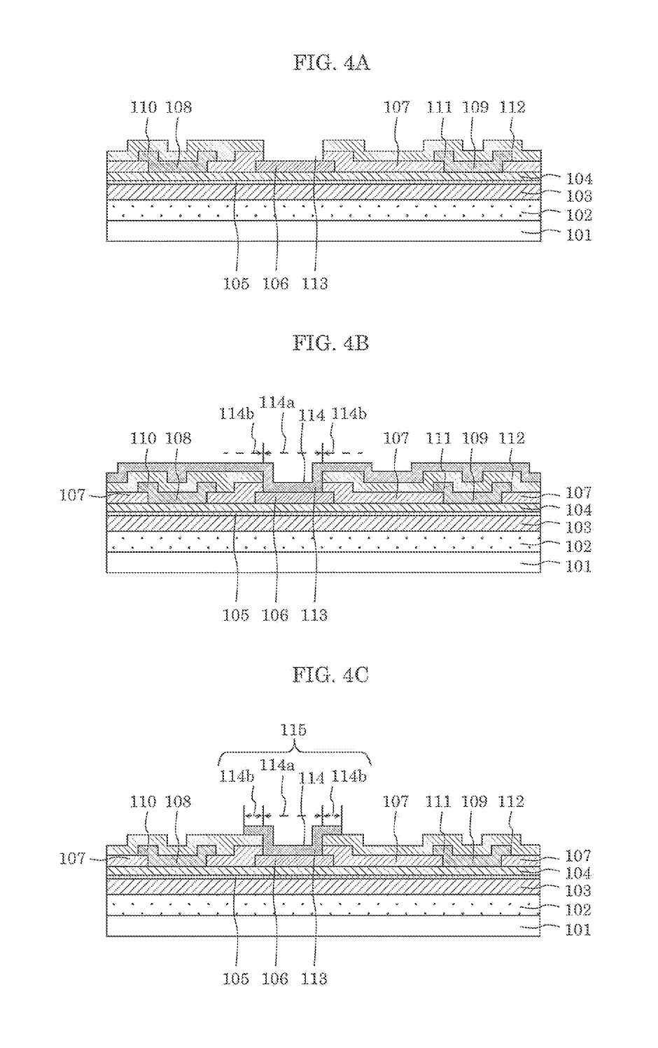

FIGS. 2A to 2D, 3A to 3C, and 4A to 4C are cross-sectional views illustrating the nitride semiconductor device manufacturing method according to Embodiment 1. FIGS. 2A to 2D, 3A to 3C, and 4A to 4C illustrate a sequence of steps, that is, the step illustrated in FIG. 2D is followed by the step illustrated in FIG. 3A, and the step illustrated in FIG. 3C is followed by the step illustrated in FIG. 4A.

First, buffer layer 102 having a thickness of 2 μm and a stacked structure of AN and AlGaN, i-type GaN layer 103 having a thickness of 2 μm, and i-type AlGaN layer 104 having a thickness of 600 nm and an Al composition ratio of 15% are sequentially epitaxially grown on Si substrate 101 by metal-organic chemical vapor deposition (MOCVD) as illustrated in FIG. 2A. As a result, two-dimensional electron gas 105 is generated at the heterointerface between i-type AlGaN layer 104 and i-type GaN layer 103.

Then, p-type GaN layer 106 having a thickness of 200 nm is epitaxially grown on the surface of i-type AlGaN layer 104 by MOCVD as illustrated in FIG. 2B. The Mg concentration in p-type GaN layer 106 is set to 5×10¹s cm⁻³. In this condition, Mg is neutralized as a result of forming Mg—H complexes with H. After this, heat treatment is performed, for example, at 1000° C. for 30 minutes in N2 atmosphere. As a result, approximately 1% of Mg is activated and acceptor ions are generated at a concentration of approximately 5×10¹⁷ cm⁻³ in p-type GaN layer 106.

Then, p-type GaN layer 106 is processed into a predetermined shape by sequentially applying lithography and etching as illustrated in FIG. 2C. In the case of using dry etching, the etching rate of p-type GaN layer 106 may be set to a smaller value than the etching rate of i-type AlGaN layer 104 by adding an oxygen gas to a chlorine gas.

Then, SiN film 107 having a thickness of 100 nm is deposited on the surfaces of i-type AlGaN layer 104 and p-type GaN layer 106 by plasma CVD as illustrated in FIG. 2D. Here, SiH₄ and NH₃ are used as source gases. The Si content in SiN film 107 may be adjusted by adjusting the flow ratio of these two gases. In the present embodiment, the Si content in SiN film 107 is set to 50%.

Then, source opening 108 and drain opening 109, which reach i-type AlGaN layer 104, are formed in predetermined regions of SiN film 107 by sequentially applying lithography and etching as illustrated in FIG. 3A. The etching may adopt a method using a high etching rate for SiN film 107 and a low etching rate for i-type AlGaN layer 104.

Then, source electrode 110 and drain electrode 111 are formed to respectively cover source opening 108 and drain opening 109 by sequentially applying lithography and etching after sequential deposition of a Ti film and an Al film as illustrated in FIG. 3B. After this, heat treatment is performed at 600° C. in N2 atmosphere to establish ohmic contact between these electrodes and two-dimensional electron gas 105 generated at the heterointerface between i-type AlGaN layer 104 and i-type GaN layer 103.

Then, SiN film 112 having a thickness of 100 nm is deposited on the surfaces of SiN film 107, source electrode 110, and drain electrode 111 by plasma CVD, as illustrated in FIG. 3C. In the present embodiment, the Si content in SiN film 112 is set to 50%, as in the case of SiN film 107.

Then, gate opening 113 that reaches p-type GaN layer 106 is formed in a predetermined region of SiN films 107 and 112 by sequentially applying lithography and etching as illustrated in FIG. 4A. The etching is conducted in two stages in the following manner. First, the films are etched to a depth of approximately 140 nm by dry etching using a CF₄ gas and then further etched to a depth of approximately 60 nm by wet etching using an HF aqueous solution. After this, the surface of p-type GaN layer 106 that is exposed to gate opening 113 is cleaned with a special agent.

Then, Ti film 114 is deposited by sputtering on the surfaces of p-type GaN layer 106 and SiN film 107 that are exposed to gate opening 113, as illustrated in FIG. 4B. Ti film 114 includes Ti film 114a that is in contact with p-type GaN layer 106, and Ti film 114b that is in contact with SiN film 112. Ti film 114a is coherently or metamorphically grown on p-type GaN layer 106.

In the last step, gate electrode 115 is formed to cover gate opening 113 by sequentially applying lithography and etching as illustrated in FIG. 4C. This completes the manufacture of the nitride semiconductor device according to the present embodiment.

Thereafter, passivation films, multilayer interconnection, and bonding pads may be formed as necessary.

The reason for adopting the two-stage etching in the step illustrated in FIG. 4A will now be described. Using only dry etching is desirable from the viewpoint of ensuring lateral size controllability. However, if the dry etching reaches p-type GaN layer 106, physical shock caused by ions in plasma will disturb the crystallinity of the surface of p-type GaN layer 106. This consequently makes it difficult for Ti film 114a to be favorably grown coherently or metamorphically on p-type GaN layer 106 in the step illustrated in FIG. 4B. Thus, in the present embodiment, dry etching is stopped in midstream and wet etching that causes no physical shock is used for the residual etching in order to prevent the etching process from disturbing the crystallinity of the surface of p-type GaN layer 106.

Next, the reason for cleaning the surface of p-type GaN layer 106 exposed to gate opening 113 with a special agent in the step illustrated in FIG. 4A will be described. After etching, an oxide layer exists on the surface of p-type GaN layer 106. In this condition, it is difficult for Ti film 114a to be favorably grown coherently or metamorphically on p-type GaN layer 106 in the step illustrated in FIG. 4B. Thus, in the present embodiment, the oxide layer on the surface of p-type GaN layer 106 is removed using a special agent. In the present embodiment, the special agent may be an agent that contains NH₄F, dimethyl formaldehyde, and tetramethylammonium formate.

An exemplary time interval between the cleaning step using the special agent illustrated in FIG. 4A and the step illustrated in FIG. 4B will now be described. The time interval between the cleaning step using the special agent in FIG. 4A and the step in FIG. 4B may be set to within 24 hours. This is because the time interval longer than 24 hours will result in generation of a non-negligible amount of oxide layer on the surface of p-type GaN layer 106. In this condition, it is difficult for Ti film 114a to be favorably grown coherently or metamorphically on p-type GaN layer 106 in the step illustrated in FIG. 4B.

Next, an exemplary form of deposition of Ti film 114 in the step illustrated FIG. 4B will be described. The step of depositing Ti film 114 may use sputtering, rather than electron-beam evaporation or resistance heating evaporation generally used in the manufacture of compound semiconductors. This is because the process of causing Ti atoms having high, uniform kinetic energy to come flying over the surface of p-type GaN layer 106 and to be rearranged by its kinetic energy on the surface of p-type GaN layer 106 will militate in favor of allowing Ti film 114a to be favorably grown coherently or metamorphically on p-type GaN layer 106 in the step illustrated in FIG. 4B.

Next, an exemplary form of steps subsequent to the step illustrated in FIG. 4C will be described. Steps subsequent to the step illustrated in FIG. 4C may be performed at temperatures that are maintained at 360° C. or less. This is because, if Ti film 114a is placed at temperatures higher than 360° C. in steps subsequent to the step in FIG. 4C, it will become difficult to maintain a state in which Ti film 114a has favorably grown coherently or metamorphically on p-type GaN layer 106.

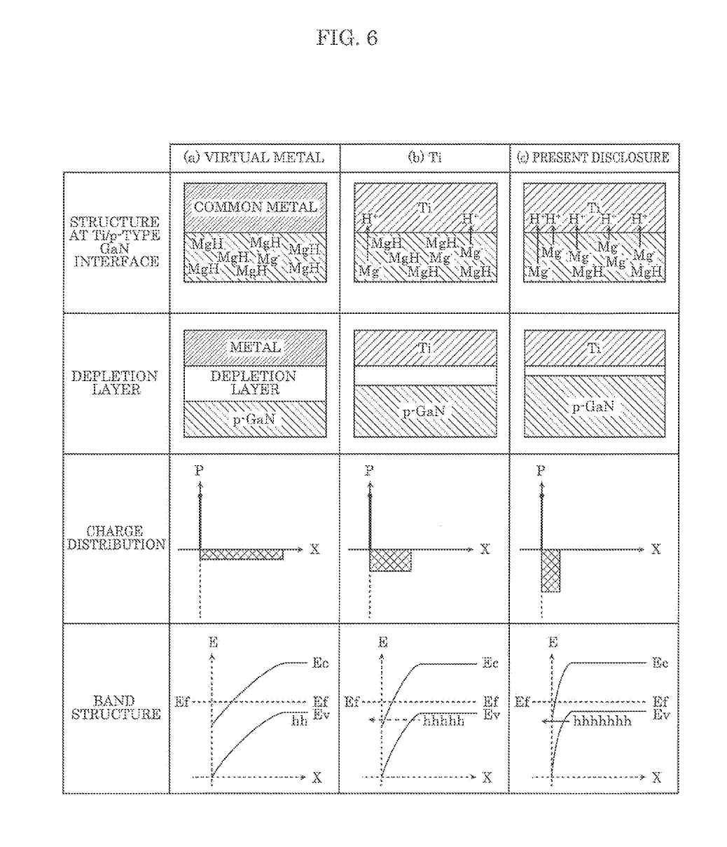

Hereinafter, a mechanism using the above-described structure to improve contact characteristics at the Ti/p-type GaN interface will be described. The inventors of the present disclosure have focused their attention on a band structure at the Ti/p-type GaN interface and carried out various theoretical and experimental studies on the band structure in order to improve contact characteristics. As a result, they have found that a depletion layer to be formed at the Ti/p-type GaN interface will be downsized and contact characteristics will be improved by causing Ti, which is grown coherently or metamorphically, to diffuse H into p-type GaN and thereby increasing the density of acceptor ions, as summarized in FIG. 6, which will be described later.

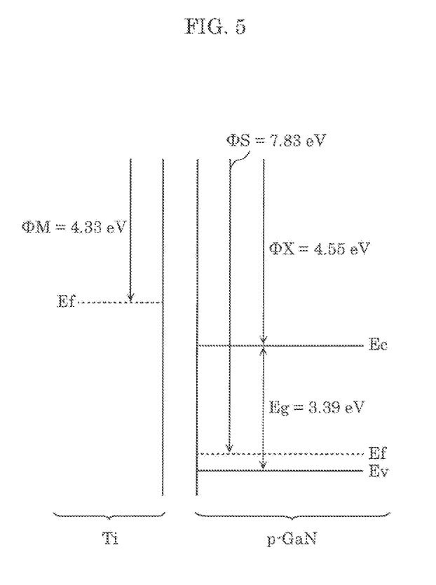

FIG. 5 illustrates a band structure when Ti and p-type GaN are independent of each other. FIG. 6 is a comprehensive diagram illustrating a mechanism that will improve contact characteristics at the Ti/p-type GaN interface. As illustrated in FIG. 5, Ti has a work function of 4.33 eV, and p-type GaN has a work function of 7.83 eV, that is, p-type GaN has a higher work function. In other words, Ti has a higher Fermi level than p-type GaN.

Next, consider a virtual metal that has the same band structure as that of Ti illustrated in FIG. 5. The structure at the metal/p-type GaN interface, the depletion layer, the charge distribution, and the band structure when this metal is joined to p-type GaN are as illustrated in (a) in FIG. 6. Since the metal has a higher Fermi level than p-type GaN, the joining of the metal and p-type GaN causes electrons to move from the metal to p-type GaN. Along with this, at the surface of p-type GaN, holes serving as carriers recombine with electrons and disappear, and a depletion layer is formed in which only acceptor ions remain. As a result of the negative electric charge of the acceptor ions generating an electric field in such a direction as to prevent the motion of electrons, a Schottky contact is formed as a new equilibrium state.

Next, a case of joining Ti and p-type GaN as in the present embodiment will be described. The structure at the Ti/p-type GaN interface, the depletion layer, the charge distribution, and the band structure in this case are as illustrated in (b) in FIG. 6. Because Ti is known as a hydrogen storage metal, the joining of Ti and p-type GaN causes some H in p-type GaN to diffuse into Ti. As a result, in the vicinity of the surface of p-type GaN, the number of Mg—H complexes decreases and the number of acceptor ions increases. Thus, the width of the depletion layer decreases as compared with the case of using a common metal. As a result, the tunnel effect will appear and the contact characteristics at the metal/p-type GaN interface will be improved.

Here, the inventors of the present disclosure have found out that it is possible to further improve the contact characteristics at the metal/p-type GaN interface by causing Ti to be coherently or metamorphically grown on p-type GaN. The reason will be described below.

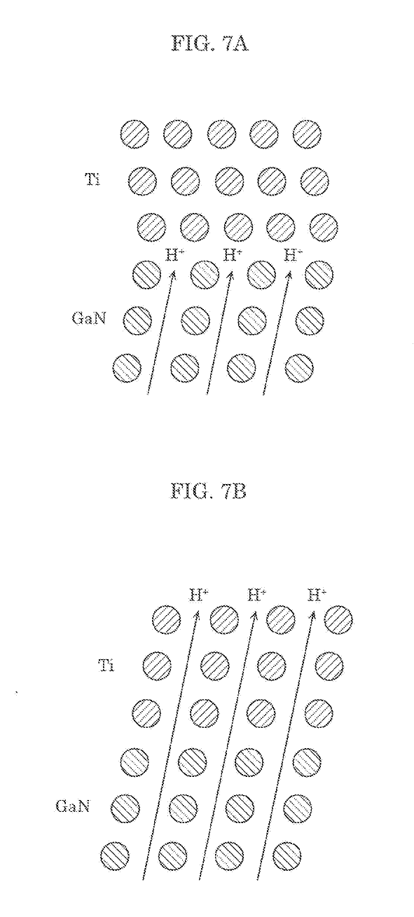

Ti that is not coherently or metamorphically grown will have an amorphous or polycrystalline structure in the vicinity of p-type GaN. With Ti having such a structure, the structure at the Ti/p-type GaN interface is as illustrated in FIG. 7A, in which lattice mismatch occurs at an extremely high density between Ti and p-type GaN.

FIG. 7A illustrates the structure at the Ti/p-type GaN interface. This lattice mismatch considerably inhibits the diffusion of H from p-type GaN into Ti. As a result, the downsizing of the depletion layer formed at the Ti/p-type GaN interface is insufficient as illustrated in (b) in FIG. 6, and good contact characteristics will not be achieved.

On the other hand, if Ti is grown coherently or metamorphically on p-type GaN as in the present embodiment, the density of lattice mismatch between Ti and p-type GaN will decrease considerably as illustrated in FIG. 7B.

FIG. 7B illustrates the structure at the Ti/p-type GaN interface. As a result, H will be diffused effectively from p-type GaN into Ti, and the depletion layer formed at the Ti/p-type GaN interface will be downsized sufficiently as illustrated in (c) in FIG. 6. Accordingly, good contact characteristics will be achieved.

In the above description, the charge distribution in the depletion layer is approximated to a rectangle in order to simplify the discussion. However, it would be apparent for those skilled in art that the essence of the phenomenon will remain unchanged even if the charge distribution has a more complicated shape such as the shape of an exponential function.

Now, the definitions of the terms “coherent growth” and “metamorphic growth” will be described. The following is a Japanese translation of the main points of Non-Patent Literature 1 (Yong Lin, “SCIENCE AND APPLICATIONS OF III-V GRADED ANION METAMORPHIC BUFFERS ON InP SUBSTRATES,” dissertation, pp. 35-36, The Ohio State University, 2007).

(1) For crystal growth of a layer on a base substrate with a different lattice constant, if the thickness of the layer is smaller than a critical value (hc), the lattice of the layer will become deformed and the layer will be grown while maintaining lattice continuity. This is called pseudomorphic growth (the terms “pseudomorphic growth” and “coherent growth” have the same meaning). (2) On the other hand, if the thickness of the layer exceeds the critical value, strain relaxation occurs through the introduction of misfit dislocations at the interface. This is called metamorphic growth.

The application of metamorphic growth is found in, for example, Japanese Unexamined Patent Application Publication 2008-085018 (Patent Literature 3). In this example, a metamorphically grown intermediate layer (metamorphic buffer layer) is used to grow an InP layer on a GaAs substrate. This intermediate layer has the role of relaxing lattice mismatch between the GaAs substrate and the InP layer by confining crystal defects.

From the foregoing, the present disclosure defines the concepts of “coherent” and “metamorphic” in the following manner.

The term “coherent” refers to a state in which the deformation of the lattice of a layer (film) allows the layer (film) to hold crystal information of a base substrate.

The term “metamorphic” refers to a state in which the introduction of defects into a layer (film) allows the layer (film) as a whole to hold crystal information of a base substrate.

Also, a state in which a layer (film) is coherent (or metamorphic) is referred to as a “coherent state (or metamorphic state),” and a state in which a layer (film) is coherently (or metamorphically) grown is referred to as “coherent (or metamorphic) growth.”

Next is a description of results obtained by evaluating the film quality of Ti film 114a generated by the nitride semiconductor device manufacturing method according to Embodiment 1. The evaluation primarily uses an X-ray diffraction (XRD) method. In general, XRD measurement requires large-area samples with a radius of several centimeters. Thus, samples are prepared by a method based on the actual manufacturing method with some contrivance to increase the area of contact between Ti film 114a and p-type GaN layer 106. For the thickness of Ti film 114a, three different levels of samples, i.e., 5-nm-thick, 10-nm-thick, and 60-nm-thick Ti films 114a, are prepared in order to study the relationship between thickness and crystal structure.

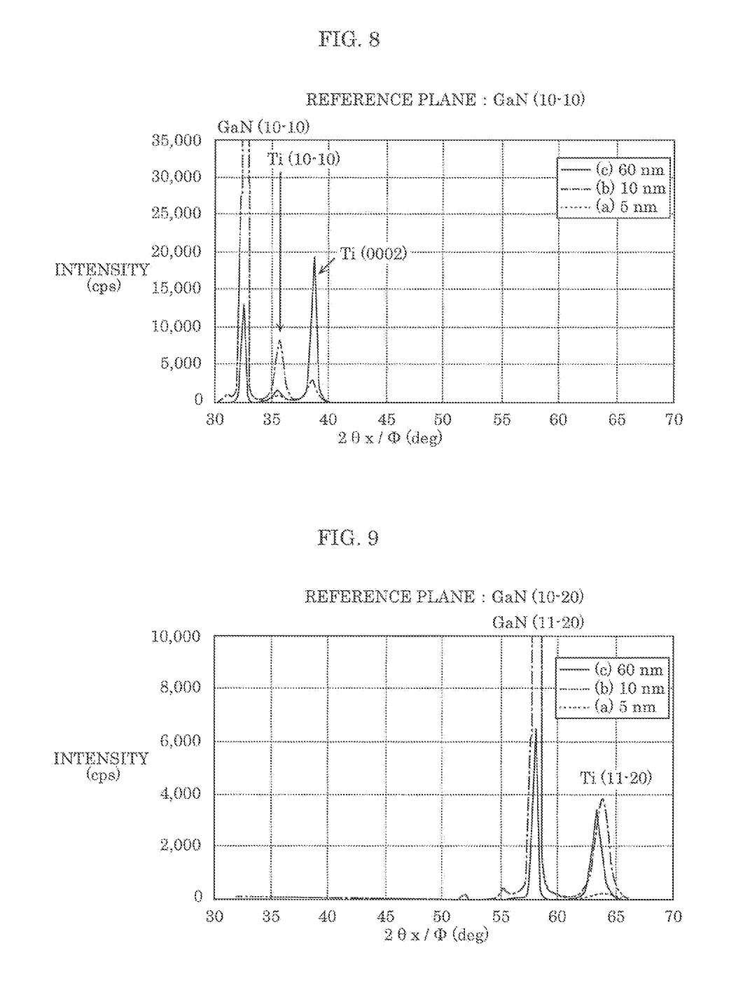

FIG. 8 illustrates XRD spectra obtained by in-plane θ-2θ measurement. FIG. 8 shows the results when the samples are installed such that the (11-10) plane of GaN becomes orthogonal to the incident X-ray. In FIG. 8, (a) shows the spectrum for 5-nm thick Ti film 114a, (b) shows the spectrum for 10-nm thick Ti film 114a, and (c) shows the spectrum for 60-nm thick Ti film 114a. For 5-nm thick Ti film 114a, a high peak appears at 2θ=32.41°. This is due to diffraction in the (10-10) plane of GaN. A peak also appears at 2θ=35.75°. This is due to diffraction in the (10-10) plane of Ti. In the current measurement range of 2θ from 30° to 70°, diffraction in other planes, namely, (0002), (10-11), (10-12), and (11-20) planes of Ti, is also detectable, but no corresponding peaks appear in the spectra. For 10-nm and 60-nm thick Ti films 114a, a peak also appears at 2θ=38.5°, in addition to the peaks in the (10-10) plane of GaN and the (10-10) plane of Ti. This peak is due to diffraction in the (0002) plane of Ti.

Next, the samples are installed such that the (11-20) plane of GaN becomes orthogonal to the incident X-ray, and XRD spectra are measured by rotating the samples and a detector so that a rotation angles φ of the samples and a rotation angle θ of the detector satisfy θ=2φ.

FIG. 9 illustrates XRD spectra obtained by in-plane θ-2θ measurement. In FIG. 9, (a) shows the spectrum for 5-nm thick Ti film 114a, (b) shows the spectrum for 10-nm thick Ti film 114a, and (c) shows the spectrum for 60-nm thick Ti film 114a. Regardless of the thickness, a high peak appears at 2θ=57.80°. This is due to diffraction in the (11-20) plane of GaN. A peak also appears at 2θ=63.6°. This is due to diffraction in the (11-20) plane of Ti. In the current measurement range of 2θ from 30° to 70°, diffraction in other planes, namely, (10-10), (0002), (10-11), (10-12), and (11-20) planes of Ti, is also detectable, but no corresponding peaks appear in the spectra.

Table 1 provides a summary of peaks appearing in the spectra illustrated in FIGS. 8 and 9.

TABLE 1

| | | Reference Plane = | | | Reference Plane = | | |
|---|---|---|---|---|---|---|---|
| Diffraction | 2θ | GaN (11-10) | | | GaN (11-20) | | |
| Plane | (°) | 5 nm | 10 nm | 60 nm | 5 nm | 10 nm | 60 nm |
| GaN (10-10) | 32.41 | ∘ | ∘ | ∘ | x | x | x |
| Ti (10-10) | 35.09 | ∘ | ∘ | ∘ | x | x | x |
| Ti (0002) | 38.42 | x | ∘ | ∘ | x | x | x |
| Ti (10-11) | 40.17 | x | x | x | x | x | x |
| Ti (10-12) | 53.00 | x | x | x | x | x | x |
| GaN (11-20) | 57.91 | x | x | x | ∘ | ∘ | ∘ |
| Ti (11-20) | 62.94 | x | x | x | ∘ | ∘ | ∘ |

The following can be seen from Table 1.

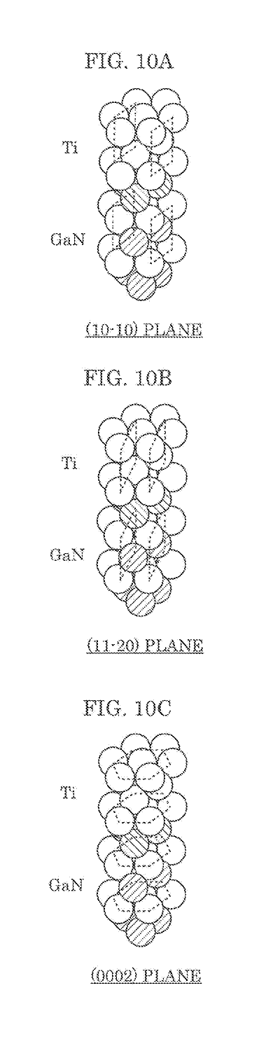

(1) Peaks appear in such a manner that the (10-10) plane of GaN and the (10-10) plane of Ti always correspond to each other, and the (11-20) plane of GaN and the (11-20) plane of Ti always correspond to each other. From this, it can be thought that Ti film 114a has inherited the crystal information of p-type GaN layer 106 during its growth. This is schematically illustrated in FIGS. 10A to 10C.

FIG. 10A illustrates (10-10) planes at the Ti/p-type GaN interface. FIG. 10B illustrates (11-20) planes at the Ti/p-type GaN interface. FIG. 10C illustrates (0002) planes at the Ti/p-type GaN interface. As illustrated in FIG. 10C, the (0002) plane of GaN and the (0002) plane of Ti are parallel to each other when Ti film 114a has inherited the crystal information of p-type GaN layer 106 during its growth.

(2) If the thickness of Ti film 114a is increased to approximately 10 nm, a new layer appears, in which the (10-10) plane of GaN is parallel to the (0002) plane of Ti. In this case, it is conceivable that Ti film 114a includes two layers having different crystalline properties.

In order to study such a new layer that will appear when Ti film 114a has a thickness of 10 nm or more, a sample is prepared by further depositing an Al film on Ti film 114a. Ti film 114a and the Al film respectively have thicknesses of 20 nm and 200 nm. The Al film is deposited by sputtering. Ti film 114a and the Al film are continuously deposited in a vacuum.

Then, an XRD spectrum for this sample is measured by fixing the rotation angle (θ) of the detector in accordance with specific diffraction and then changing only the rotation angle (φ) of the sample. This is a scan method called a “rocking curve method” and can measure variations in the plane orientation of a specific crystal plane included in a film.

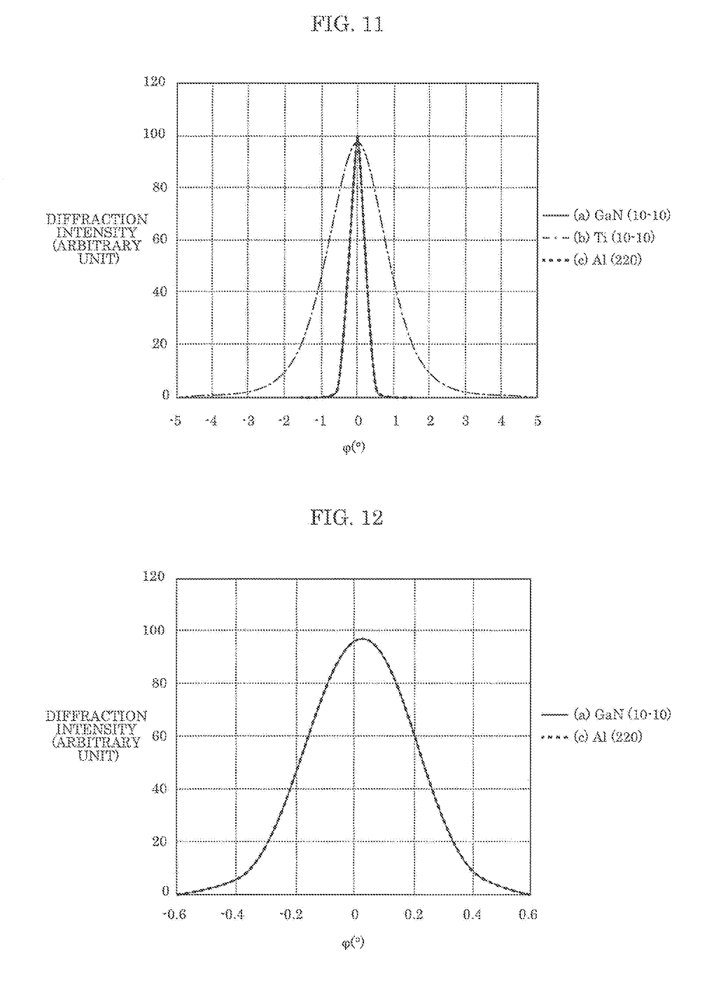

FIGS. 11 and 12 illustrate waveforms obtained by in-plane rocking curve measurement. In FIG. 11, (a) shows variations in the plane orientation of the (10-10) plane of GaN, which are measured by setting θ to the diffraction angle) (32.41° in the (10-10) plane of GaN, (b) shows variations in the plane orientation of the (10-10) plane of Ti, which are measured by setting θ to the diffraction angle) (35.75° in the (10-10) plane of Ti, and (c) shows variations in the plane orientation of the (220) plane of Al, which are measured by setting θ to the diffraction angle) (67.8° in the (220) plane of Al. These waveforms are standardized so that their maximum values match.

First, the relationship between (a) and (b) is focused on. The half-value width for (b) is approximately three times greater than the half-value width for (a). This implies that the difference in lattice constant between p-type GaN layer 106 and Ti film 114a may generate crystal defects in Ti film 114a in the vicinity of the Ti/p-type GaN interface. Next, the relationship between (a) and (c) is focused on. In FIG. 11, the waveforms (a) and (c) overlap each other and cannot be distinguished. In view of this, FIG. 12 shows only the waveforms (a) and (c) extracted from FIG. 11, with a considerably enlarged scale on the horizontal axis.

As illustrated in FIG. 12, the waveforms (a) and (c) are almost identical even if the scale on the horizontal axis is set to an extremely narrow range from −0.6° to 0.6°. This indicates that the Al film has completely inherited the crystal information of p-type GaN layer 106 during its growth.

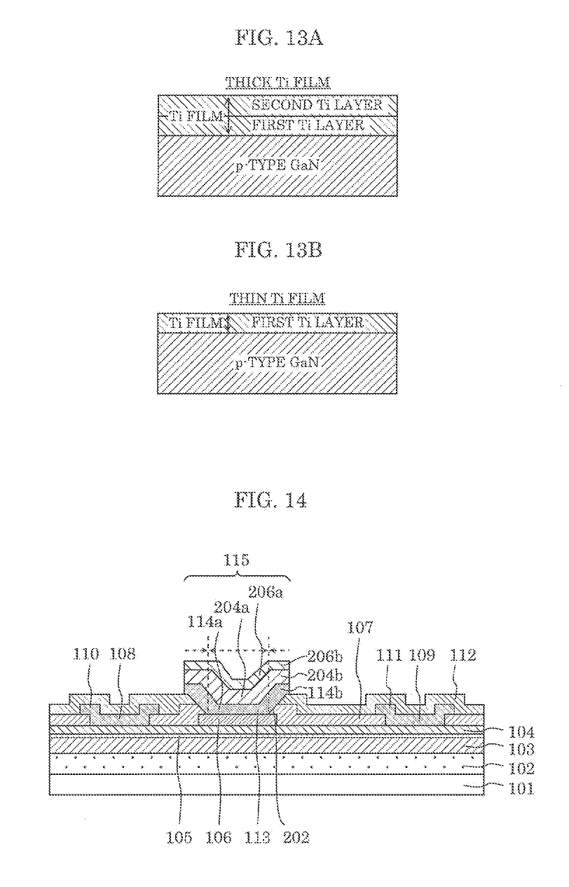

FIGS. 13A and 13B illustrate a summary of conclusions obtained from the above-described measurement results.

FIG. 13A is a cross-sectional view illustrating a structure obtained from the XRD measurement results for a thick Ti film. FIG. 13A illustrates the case of thick Ti film 114a, e.g., 10-nm thick Ti film 114a or 60-nm thick Ti film 114a. In this case, Ti film 114a contains defects as described above. However, the Al film deposited on Ti film 114a has completely inherited the crystal information of p-type GaN layer 106 during its growth. This is a feature of metamorphic growth, as described in Patent Literature 3. Thus, when Ti film 114a is thick, it can be the that Ti film 114a is grown metamorphically on p-type GaN. Moreover, it is conceivable from the measurement results illustrated in FIG. 8 that this Ti film includes two layers: (1) a layer (first Ti layer) in which the (10-10) plane of Ti is parallel to the (10-10) plane of GaN; and (2) a layer (second Ti layer) in which the (0002) plane of Ti is parallel to the (10-10) plane of GaN.

FIG. 13B is a cross-sectional view illustrating a structure obtained by the XRD measurement results for a thin Ti film. FIG. 13B illustrates the case of thin Ti film 114a, e.g., 5-nm thick Ti film 114a. In this case, it is conceivable that the Ti film is grown coherently on p-type GaN, because Non-Patent Literature 1 has pointed out the occurrence of coherent growth as preparation before metamorphic growth.

A desired thickness of Ti film 114a will now be described. The thickness of Ti film 114a may be set in the range of 5 nm to 60 nm. This is because it has been ascertained that Ti film 114a having a thickness within this range will be coherently or metamorphically grown on p-type GaN layer 106. Thus, contact characteristics at the Ti/p-type GaN interface can be improved with reliability.

According to the present embodiment, a power switching FET capable of high-speed switching will be provided by reducing the resistance at the contact between the p-type nitride semiconductor layer and the metal line layer.

### Embodiment 2

FIG. 14 is a cross-sectional view of a nitride semiconductor device according to Embodiment 2. As illustrated in FIG. 14, the nitride semiconductor device according to the present embodiment includes, for example, substrate 101 made of Si, buffer layer 102 having a thickness of 2 μm and having a stacked structure of a plurality of layers including AlN and AlGaN, undoped (i-type) GaN layer 103 having a thickness of 2 μm, and i-type AlGaN layer 104 having a thickness of 25 nm and an Al composition ratio of 15%, in such a manner that buffer layer 102, i-type GaN layer 103, and i-type AlGaN layer 104 are formed on substrate 101. Two dimensional electron gas 105 is generated at the heterointerface between i-type AlGaN layer 104 and i-type GaN layer 103. The nitride semiconductor device according to the present embodiment also includes p-type GaN layer 106 having a thickness of 200 nm and being processed in a predetermined shape on the surface of i-type AlGaN layer 104. Here, p-type GaN layer 106 is doped with Mg at a concentration of 5×10¹⁹ cm⁻³.

The nitride semiconductor device according to the present embodiment further includes SiN film 107 on the surfaces of i-type AlGaN layer 104 and GaN layer 106. The Si content in SiN film 107 is approximately 50%. This ratio is higher than the stoichiometric mixture ratio (43%).

SiN film 107 has source opening 108 and drain opening 109 that reach i-type AlGaN layer 104 and in which source electrode 110 and drain electrode 111 are respectively provided to cover the openings. Source electrode 110 and drain electrode 111 have a structure in which a Ti film and an Al film are sequentially stacked on top of each other, and establish electrical contact with two-dimensional electron gas 105 generated at the heterointerface between i-type AlGaN layer 104 and i-type GaN layer 103.

Another SiN film 112 is formed on the surfaces of SiN film 107, source electrode 110, and drain electrode 111. As in the case of SiN film 107, the Si content in SiN film 112 is approximately 50%.

SiN films 107 and 112 have gate opening 113 that reaches p-type GaN layer 106. Acute angle 202 formed by the side wall of this opening and the surface of p-type GaN layer 106 is 45 degrees or less. Gate electrode 115 is formed to cover gate opening 113. Gate electrode 115 includes Ti film 114a that is in contact with p-type GaN layer 106, Al film 204a that is in contact with Ti film 114a, Ti film 206a that is in contact with Al film 204a, Ti film 114b that is in contact with SiN film 112, Al film 204b that is in contact with Ti film 114b, and Ti film 206b that is in contact with Al film 204b. Ti films 114a and 114b both have a thickness of 10 nm. Al films 204a and 204b have a thickness of 400 nm or more. Ti film 114a is coherently or metamorphically grown on p-type GaN layer 106. A portion of Ti film 114a that is at least within 5 nm from the interface between p-type GaN layer 106 and Ti film 114a is not alloyed. The phrase “not making an alloy” as used herein refers to, for example, a state in which no significant diffusion is observed between two metal layers by physical analysis using, for example, a secondary ion mass spectrometry (SIMS). However, there may be cases in which approximately 1% or less of atoms in one metal layer may exist as impurities among atoms in the other metal layer.

Al film 204a is epitaxially grown on Ti film 114a. That is, the crystal plane (111) of Al film 204a is grown on the crystal plane (0002) of Ti film 114a, and the crystal plane (220) of Al film 204a is grown on the crystal plane (10-10) of Ti film 114a. The rest of the configuration is the same as that of the nitride semiconductor device according to Embodiment 1.

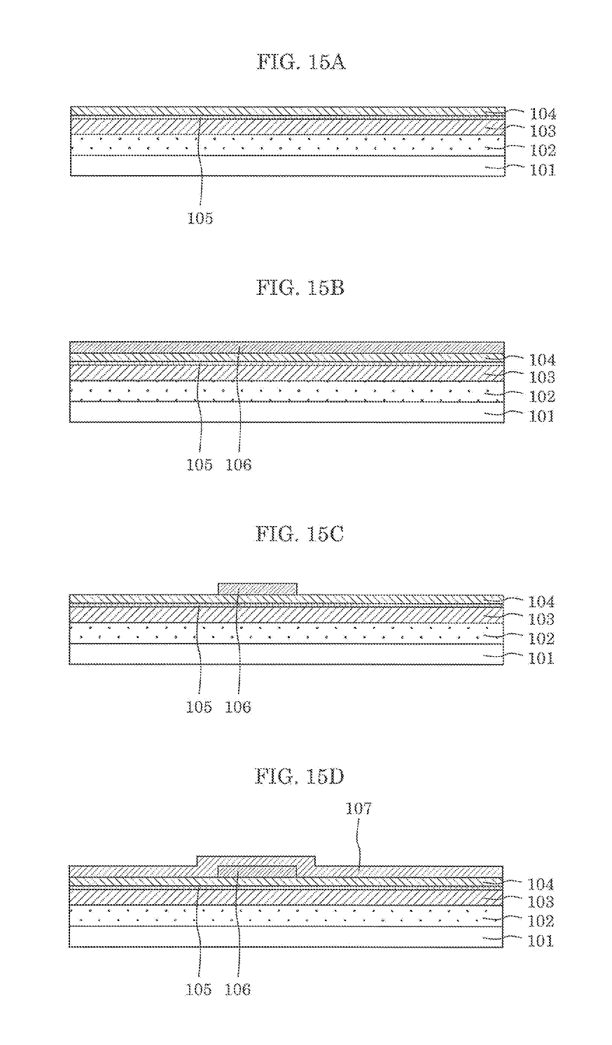

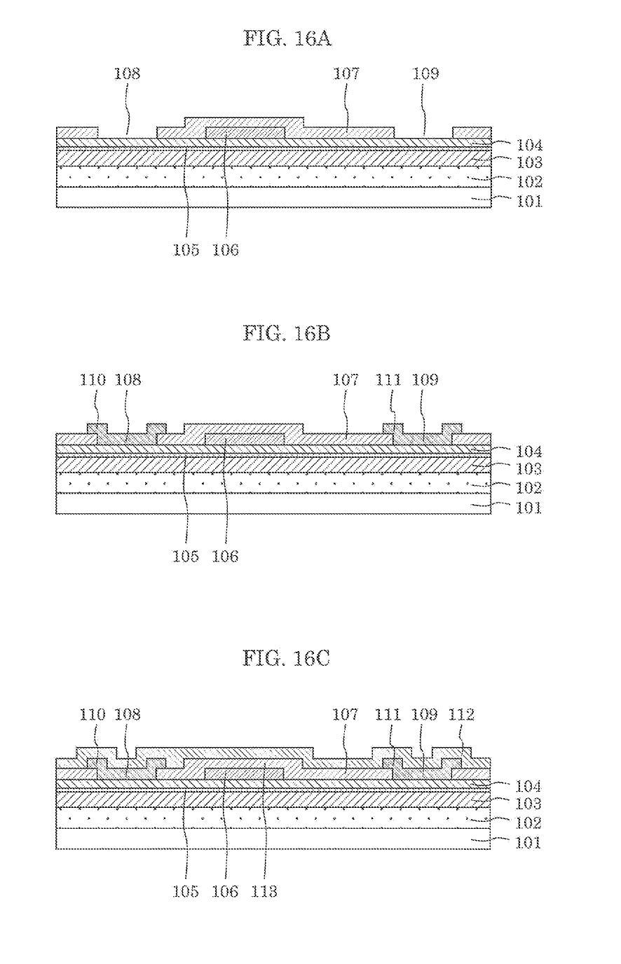

Hereinafter, a nitride semiconductor device manufacturing method according to Embodiment 2 will be described with reference to FIGS. 15A to 15D, 16A to 16C, and 17A to 17C.

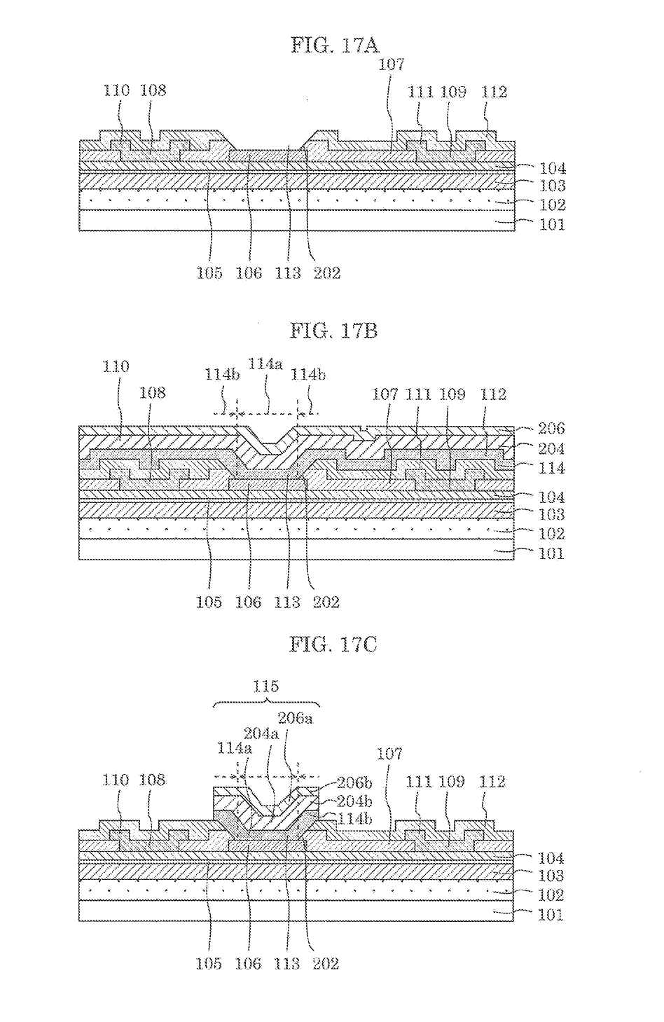

FIGS. 15A to 15D, 16A to 16C, and 17A to 17C are cross-sectional views illustrating the nitride semiconductor device manufacturing method according to Embodiment 2. FIGS. 15A to 15D, 16A to 16C, and 17A to 17C illustrate a sequence of steps, i.e., the step illustrated in FIG. 15D is followed by the step illustrated in FIG. 16A, and the step illustrated in FIG. 16C is followed by the step illustrated in FIG. 17A.

The steps illustrated in FIGS. 15A to 15D and 16A to 16C are the same as the steps illustrated in FIGS. 2A to 2D and 3A to 3C described in Embodiment 1, and therefore a description thereof will be omitted.

As illustrated in FIG. 17A, gate opening 113 that reaches p-type GaN layer 106 is formed in a predetermined region of SiN films 107 and 112 by sequentially applying lithography and etching. The etching is conducted in two stages in the following manner. First, the films are etched to a depth of approximately 140 nm by dry etching using a CF₄ gas and then further etched to a depth of approximately 60 nm by wet etching using an HF aqueous solution. After this, the surface of p-type GaN layer 106 that is exposed to gate opening 113 is cleaned with a special agent. Acute angle 202 formed by the side wall of this opening and the surface of p-type GaN layer 106 is controlled to become 45 degrees or less by adjusting, for example, a resist material for use in lithography, adhesion properties of SiN film 112 at the interface, and wet etching time.

Then, Ti film 114, Al film 204, and Ti film 206 are deposited in this order by sputtering on the surfaces of p-type GaN layer 106 and SiN film 107 that are exposed to gate opening 113 as illustrated in FIG. 17B. Ti film 114 includes Ti film 114a that is in contact with p-type GaN layer 106, and Ti film 114b that is in contact with SiN film 112. Ti film 114a is coherently or metamorphically grown on p-type GaN layer 106. A portion of Ti film 114a that is within 5 nm from the interface between p-type GaN layer 106 and Ti film 114a is not alloyed with Al. Al film 204a is epitaxially grown on Ti film 114a. The epitaxial growth in this case refers to a state in which the (0002) plane of Ti film 114a and the (111) plane of Al film 204a are each parallel to the (0002) plane of the p-type GaN layer, the (10-10) plane of Ti film 114a and the (220) plane of Al film 204a are each parallel to the (10-10) plane of the p-type GaN layer, and Al film 204a does not contain crystals forming other planes, excluding irregularities of crystals in several atomic layers, such as crystal defects or dislocations.

In the last step, gate electrode 115 is formed to cover gate opening 113 by sequentially applying lithography and etching as illustrated in FIG. 17C. This completes the manufacture of the nitride semiconductor device according to the present embodiment.

Thereafter, passivation films, multilayer interconnection, and bonding pads may be formed as necessary.

Two reasons for setting acute angle 202, which is formed by the side wall of opening 113 and the surface of p-type GaN layer 106, to 45 degrees or less in the step illustrated in FIG. 17A will now be described.

The first reason is because of the crystallinity of Al film 204. Since Ti film 114b, which is in contact with SiN film 112, is neither coherently nor metamorphically grown, Al film 204b, which is in contact with Ti film 114b, is not epitaxially grown. However, if acute angle 202 formed by the side wall of opening 113 and the surface of p-type GaN layer 106 is in the range of 45 degrees to 60 degrees, crystal grains of Al film 204a, which is in contact with Ti film 114a, tend to spread in lateral directions. It is also found that, if the acute angle is 45 degrees or less, gate electrode 115 as a whole often becomes a single crystal grain. The second reason is that, if Al film 204 is formed under bad conditions, a low Al concentration region will be formed in the longitudinal direction along the Al film, with a point of intersection between the side wall of opening 113 and the surface of p-type GaN layer 106 as an origin.

For these two reasons, acute angle 202 formed by the side wall of opening 113 and the surface of p-type GaN layer 106 needs to be 45 degrees or less in order to not impair the reliability of gate lines.

An exemplary form of deposition of Ti film 114 and Al film 204 in the step illustrated in FIG. 17B will now be described. The step of depositing Ti film 114 and Al film 204 may use sputtering, rather than electron-beam evaporation or resistance heating evaporation generally used in the manufacture of compound semiconductors. Moreover, the step of depositing Ti film 114 and Al film 204 by sputtering may use an apparatus that includes, for example, a high-vacuum load-lock chamber, in order to avoid the entry of oxygen or other substances during a period of time from the end of deposition of Ti film 114 to the start of deposition of Al film 204. This is because, in order for Ti film 114a to be favorably grown coherently or metamorphically on p-type GaN layer 106 in the step illustrated in FIG. 17B, it is essential for Ti atoms having high, uniform kinetic energy to come flying over the surface of p-type GaN layer 106 and to be rearranged by its kinetic energy on the surface of p-type GaN layer 106. Then, it is necessary to cause Al atoms having high, uniform kinetic energy to come flying over the surface of Ti film 114a, which is favorably grown coherently or metamorphically, and to be rearranged on Ti film 114a. At this time, it is clear that the presence of impurity elements, such as oxygen, on Ti film 114a will render such rearrangement difficult.

Next, an exemplary form of steps subsequent to the step illustrated in FIG. 17C will be described. Steps subsequent to the step illustrated in FIG. 17C may be performed at temperatures that are maintained at 320° C. or less. This is because, if Ti film 114a is placed at temperatures higher than 320° C. in steps subsequent to the step illustrated in FIG. 17C, it will become difficult to maintain a state in which Ti film 114a is favorably grown coherently or metamorphically on p-type GaN layer 106. Hereinafter, a mechanism using the Al/Ti/p-type GaN gate structure will be described, in which a metal line layer is epitaxially grown so as to exhibit high reliability. The inventors of the present disclosure have carried out various studies in order to improve contact characteristics at the Ti/p-type GaN interface and to form a highly reliable metal line layer thereon. As a result, they have found that the Al film formed on Ti, which is in a coherent or metamorphic state with respect to the p-type GaN layer, is an epitaxially grown film that has inherited the crystal information of the p-type GaN layer. Accordingly, it is possible to achieve both the reduction in resistance at the contact between the p-type GaN layer and the metal line layer and the formation of a low-resistance and highly reliable metal line layer.

Next is a description of results obtained by evaluating the film quality of the Al film generated by the nitride semiconductor device manufacturing method according to the present embodiment. The evaluation primarily uses XRD. For a similar reason to that of Embodiment 1, samples are prepared by a method based on the actual manufacturing method.

Table 2 shows the conditions of each prepared sample and the half-value width in the (111) plane of the Al film. In order to study the relationship between the thickness of Ti film 114a and the crystal structure of the Al film, two levels of samples are prepared, namely, Sample A including a 20-nm thick Ti film and Sample B including a 60-nm thick Ti film. Moreover, in order to clarify a difference in the crystallinity of the Al film between Ti film 114a and Ti film 114b, Sample C including a 20-nm thick Ti film on SiN film 112 is prepared. The above three samples all include a 200-nm thick Al film.

TABLE 2

| | | Structure of Metal Line Layer | | Rocking Curve |
|---|---|---|---|---|
| | | Ti Film | Al Film | Half-Value |
| | | Thickness | Thickness | Width (deg) |
| Sample | Base Layer | (nm) | (nm) | in Al (111) |
| A | p-type GaN | 20 | 200 | 0.27 |
| | Layer | | | |
| B | p-type GaN | 60 | 200 | 0.32 |
| | Layer | | | |
| C | SiN Film | 20 | 200 | 9.39 |

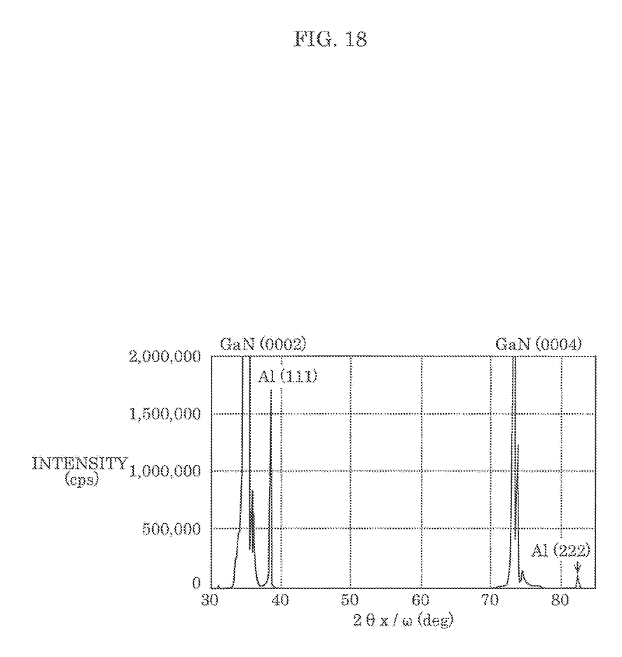

FIG. 18 illustrates an XRD spectrum obtained by out-of-plane θ-2θ measurement. More specifically, FIG. 18 illustrates the result of θ-2θ measurement for Sample A in Table 2. Table 3 shows the relationship between 2θ and lattice planes of a face-centered cubic lattice Al, which is cited from the database on powder X-ray diffraction described in Non-Patent Literature 2 (X-Ray Diffraction Database by Lightstone Corporation). Except for peaks observed in the (0002) and (0004) planes of GaN, peaks are observed only at 2θ=38.472° and at 2θ=82.435°. These peaks are respectively due to diffraction in the (111) and (222) planes of Al. In the current measurement range of 2θ from 30° to 85°, diffraction in other planes, namely, (200), (220), and (311) planes of Al, is also detectable, but no corresponding peaks appear in the spectrum.

TABLE 3

| d (Å) | I (f) | I (v) | h | k | l | n⁻2 | 2θ | θ | 1/(2d) | 2π/d |
|---|---|---|---|---|---|---|---|---|---|---|
| 2.338 | 100 | 100 | 1 | 1 | 1 | 3 | 38.472 | 19.236 | 0.2139 | 2.6874 |
| 2.024 | 47 | 54 | 2 | 0 | 0 | 4 | 44.738 | 22.369 | 0.247 | 3.1043 |
| 1.431 | 22 | 36 | 2 | 2 | 0 | 8 | 65.133 | 32.567 | 0.3494 | 4.3908 |
| 1.221 | 24 | 46 | 3 | 1 | 1 | 11 | 78.227 | 39.114 | 0.4095 | 5.1459 |
| 1.169 | 7 | 14 | 2 | 2 | 2 | 12 | 82.435 | 41.218 | 0.4277 | 5.3748 |
| 1.012 | 2 | 5 | 4 | 0 | 0 | 16 | 99.078 | 49.539 | 0.4939 | 6.2062 |
| 0.928 | 8 | 20 | 3 | 3 | 1 | 19 | 112.041 | 56.021 | 0.5383 | 6.7641 |
| 0.905 | 8 | 21 | 4 | 5 | 0 | 20 | 116.569 | 58.284 | 0.5522 | 6.9389 |
| 0.826 | 8 | 23 | 4 | 2 | 2 | 24 | 137.455 | 68.727 | 0.6049 | 7.6012 |

The XRD spectrum for this sample is measured by fixing the rotation angle (θ) of the detector in accordance with specific diffraction and then changing only a tilt angle (ω) of the sample. This is a scan method called a “rocking curve” method and can measure variations in the plane orientation of a specific crystal plane included in a film.

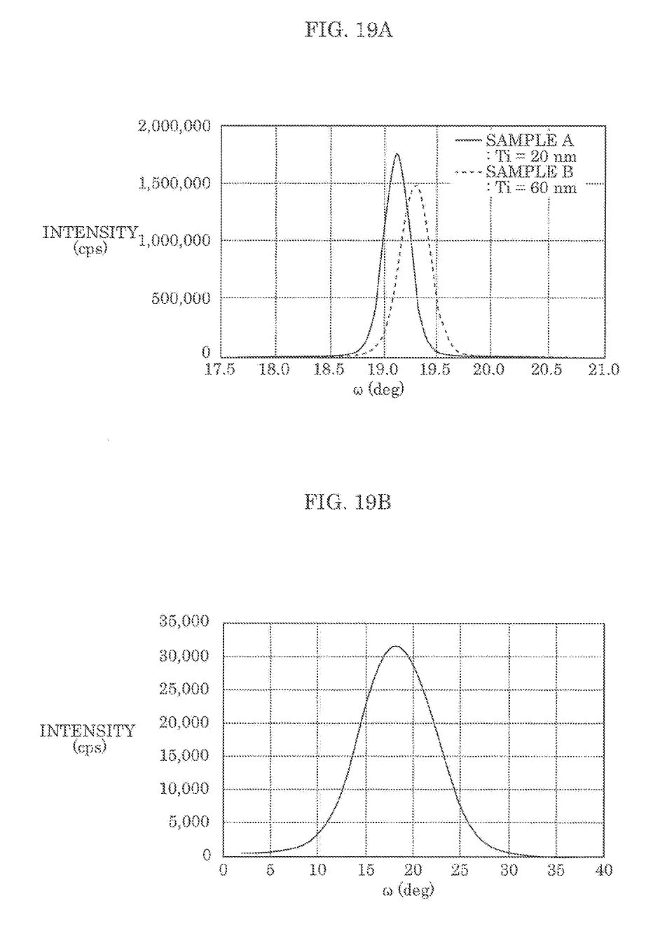

FIGS. 19A and 19B illustrate waveforms obtained by out-of-plane rocking curve measurement. FIG. 19A shows variations in the plane orientation of the (111) plane of Al, which are measured by setting 2θ to the diffraction angle (38.5°) in the (111) plane of Al. The solid line indicates the result for Sample A with a 20-nm thick Ti film in Table 2, and the broken line indicates the result for Sample B with a 60-nm thick Ti film. FIG. 19B illustrates the result of measurement for Sample C with a 20-nm thick Ti film on SiN film 112 in Table 2, which is obtained by setting 2θ to the diffraction angle (38.5°) in the (111) plane of Al. First, the relationship between Samples A and B is focused on. As shown in Table 2, the half-value width for Sample A is 0.27°, and the half-value width for Sample B is 0.32°. This indicates that the half-value width in the Al film increases with increasing thickness of the Ti film. Next, the relationship between Samples A and C is focused on. Even under the same thickness condition, i.e., 20 nm, of the Ti film, if there is no coherent or metamorphic growth on the p-type GaN layer, the half-value width in the (111) plane of the Al film for Sample C is 9.39° is an order of magnitude greater than the values for the other samples. This indicates that Al has completely different crystallinity.

One example of a method for visibly checking the crystal information of a metal film is scanning ion microscopy (SIM).

SIM is a technique for scanning a sample surface with Ga ion beams that converge to a diameter ranging from several nanometers to several hundred nanometers and then detecting and imaging generated secondary electrons. SIM is suitable for obtaining information about crystal grain sizes because contrast is generated for each crystal grain due to a phenomenon called “channeling contrast,” in which the amount of secondary electrons detected varies according to the crystal orientation of each crystal grain on the sample surface.

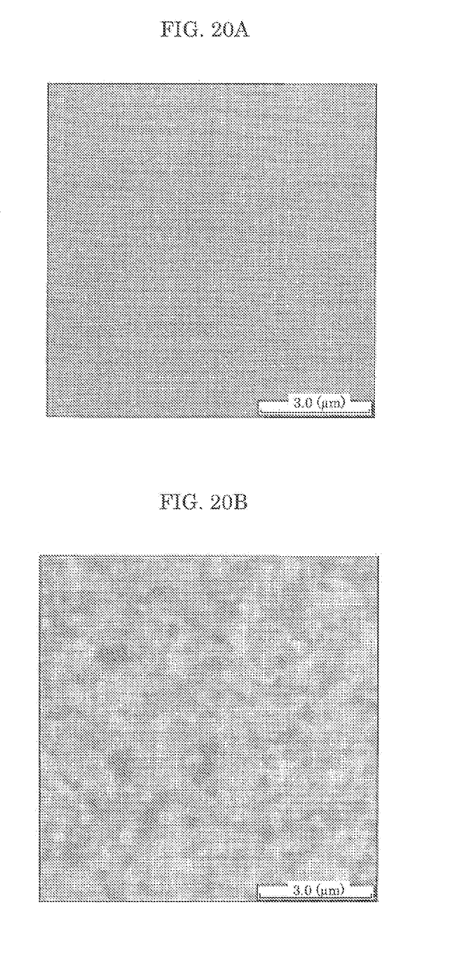

FIGS. 20A and 20B illustrate SIM images obtained by applying ion beams perpendicularly to a sample surface. More specifically, FIG. 20A illustrates an SIM image obtained by applying ion beams perpendicularly to the surface of the Al film for Sample A in Table 2, and FIG. 20B illustrates an SIM image obtained by applying ion beams perpendicularly to the surface of the Al film for Sample C in Table 2. For Sample C with an extremely high half-value width in the (111) plane of Al in XRD, clear black-and-white contrast is observed on the Al film, but for Sample A, no channeling contrast is observed on the Al film. This indicates that the Al film formed on the Ti film, which is grown coherently or metamorphically, is a film that has a (111)-oriented crystal plane parallel to the sample surface and that exhibits such high orientation that crystal planes other than the above crystal plane cannot be detected by analysis methods such as XRD and SIM.

Next, XRD measurement is conducted using an “in-plane measurement” method.

In the XRD measurement, a different spectrum will appear depending on the orientation in which samples are installed. Thus, a sample is installed so that the (10-10) plane of GaN becomes orthogonal to the incident X ray. The sample and the detector are rotated such that the rotation angle φ of the sample and the rotation angle θ of the detector satisfy θ=2φ. As described previously, this is a scan method called a “θ-2θ method” and is used to check crystal planes existing in a film.

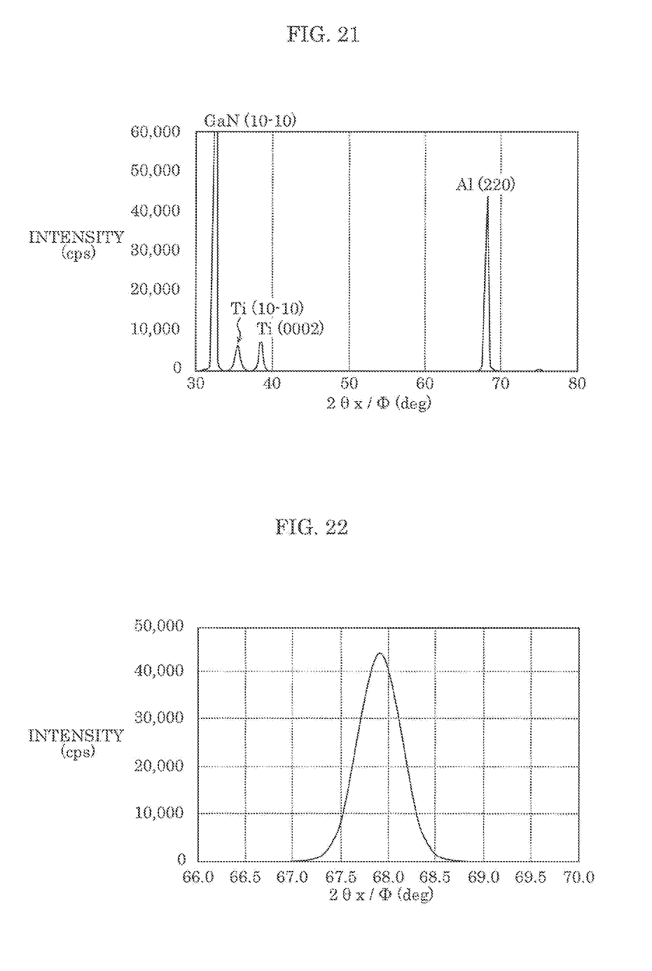

FIG. 21 illustrates an XRD spectrum obtained by in-plane 2θ measurement. More specifically, FIG. 21 illustrates the result of θ-2θ measurement for Sample A in Table 2. Except for peaks due to diffraction in GaN and the Ti film, a peak is only observed at 2θ=65. 133°. This is due to diffraction in the (220) plane of Al. In the current measurement range of 2θ from 30° to 80°, diffraction in other planes, namely, (111), (200), and (311) planes of Al, is also detectable, but no corresponding peaks appear in the spectrum.

The XRD spectrum for this sample is measured by fixing the rotation angle (θ) of the detector in accordance with specific diffraction and then changing only the tilt angle (ω) of the sample. This is a scan method called a “rocking curve” method and can measure variations in the plane orientation of a specific crystal plane included in a film.

FIG. 22 illustrates a waveform obtained by in-plane rocking curve measurement. More specifically, FIG. 22 shows variations in the plane orientation of the (220) plane of Al, which are measured by setting 2θ to the diffraction angle (67.8°) in the (220) plane of Al. That is, FIG. 22 shows the result for the (220) plane of Al of Sample A in Table 2. The half-value width in the (220) plane of Al of Sample A is 0.44°, which is greater than the half-value width in the (111) plane of Al in Table 2, but is sufficiently smaller than the half-value width for Sample C.

In this way, the Al film formed on the Ti film, which is in a coherent or metamorphic state, has completely inherited the crystal information of the base layer, i.e., p-type GaN layer, during its growth. One example of a method for checking how the crystal information of the base layer in a stacked structure has been inherited is a “reciprocal lattice map” measuring method.

The “reciprocal lattice map” measurement is a technique for two-dimensionally measuring the XRD rocking curve method and is commonly used to evaluate the crystallinity of a thin film that is epitaxially grown on a substrate.

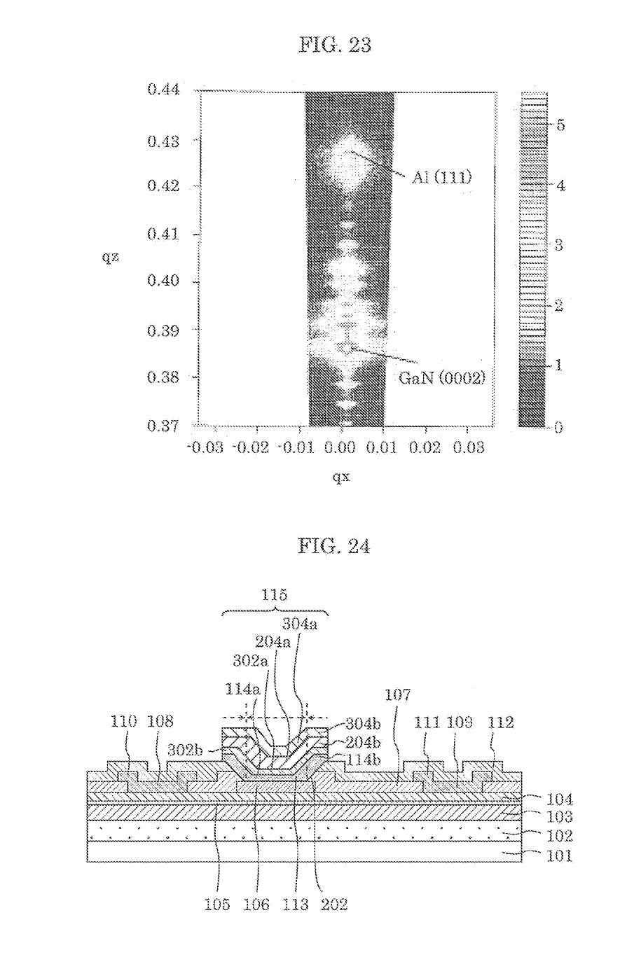

FIG. 23 illustrates a reciprocal lattice map obtained by capturing reciprocal lattice points in the (0002) plane of the p-type GaN layer and in the (111) plane of the Al film for Sample A in Table 2 by the same measurement. The reciprocal lattice points that represent the (0002) plane of the p-type GaN layer and the reciprocal lattice points that represent the (111) plane of the Al film are on the same line, and the spread of the reciprocal lattice points representing the (111) plane of the Al film converges to a small area. This indicates that the Al film formed on the Ti film, which is in a coherent or metamorphic state with respect to the p-type GaN, is an epitaxially grown Al film and a single crystal film that contains, for example, crystal defects, like the GaN layer.

It goes without saying that lines including such a single crystal Al film will exhibit high reliability during an accelerated test such as electromigration.

A desired thickness of Ti film 114a will now be described. The thickness of Ti film 114a may be set in the range of 5 nm to 60 nm. This is because it has been ascertained that Ti film 114a having a thickness within this range will be coherently or metamorphically grown on p-type GaN layer 106, and the Al film will be epitaxially grown. The Ti film with this thickness can reliably improve contact characteristics at the Ti/p-type GaN interface, and at the same time, can achieve highly reliable lines with a single crystal Al film. While the Al film in the present embodiment has a thickness of 200 nm, the thickness of the Al film may be several micrometers.

According to the present embodiment, an FET capable of high-speed switching can be achieved by reducing the resistance at the contact between the p-type nitride semiconductor layer and the metal line layer.

Conventional nitride semiconductor devices have a problem in that it is difficult to offer manufactured FETs at prices required in the market. This is because precious metals, which are used as prime materials for the metal line layer, are expensive by themselves, and in addition, not suitable for micromachining, and therefore it is not possible to lower the price of FETs by reducing the areas of the FETs.

In contrast, according to the nitride semiconductor device of the present embodiment, the metal line layer is made of a material other than precious metals so as to considerably reduce the manufacturing cost, and in addition, made into a single crystal so as to achieve high reliability. Thus, the present embodiment can provide a new power switching FET.

### Embodiment 3

FIG. 24 is a cross-sectional view of a nitride semiconductor device according to Embodiment 3. As illustrated in FIG. 24, the nitride semiconductor device according to the present embodiment includes, for example, substrate 101 made of Si, buffer layer 102 having a thickness of 2 μm and a stacked structure of a plurality of layers including AlN and AlGaN, undoped (i-type) GaN layer 103 having a thickness of 2 μm, and i-type AlGaN layer 104 having a thickness of 25 nm and an Al composition ratio of 15%, in such a manner that buffer layer 102, i-type GaN layer 103, and i-type AlGaN layer 104 are formed on substrate 101. Two dimensional electron gas 105 is generated at the heterointerface between i-type AlGaN layer 104 and i-type GaN layer 103. The nitride semiconductor device according to the present embodiment also includes p-type GaN layer 106 having a thickness of 200 nm and being processed in a predetermined shape on the surface of i-type AlGaN layer 104. Here, p-type GaN layer 106 is doped with Mg at a concentration of approximately 5×10¹⁹ cm⁻³.

The nitride semiconductor device according to the present embodiment further includes SiN film 107 on the surfaces of i-type AlGaN layer 104 and p-type GaN layer 106. The Si content in SiN film 107 is approximately 50%. This ratio is higher than the stoichiometric mixture ratio (43%).

SiN film 107 has source opening 108 and drain opening 109 that reach i-type AlGaN layer 104 and in which source electrode 110 and drain electrode 111 are respectively provided to cover the openings. Source electrode 110 and drain electrode 111 have a structure in which a Ti film and an Al film are sequentially stacked on top of each other, and establish electrical contact with two-dimensional electron gas 105 generated at the heterointerface between i-type AlGaN layer 104 and i-type GaN layer 103.

Another SiN film 112 is formed on the surfaces of SiN film 107, source electrode 110, and drain electrode 111. As in the case of SiN film 107, the Si content in SiN film 112 is approximately 50%.

SiN films 107 and 112 have gate opening 113 that reaches p-type GaN layer 106, and acute angle 202 formed by the side wall of this opening and the surface of p-type GaN layer 106 is 45 degrees or less. Gate electrode 115 is formed to cover gate opening 113. Gate electrode 115 includes Ti film 114a that is in contact with p-type GaN layer 106, titanium nitride (TiN) film 302a that is in contact with Ti film 114a, Al film 204a that is in contact with TiN film 302a, TiN film 304a that is in contact with Al film 204a, Ti film 114b that is in contact with SiN film 112, TiN film 302b that is in contact with Ti film 114b, Al film 204b that is in contact with TiN film 302b, and TiN film 304b that is in contact with Al film 204b.

Ti films 114a and 114b both have a thickness of 10 nm. TiN films 302a and 302b both have a thickness of 20 nm or more. Al films 204a and 204b have a thickness of 400 nm or more. Ti film 114a is either coherently or metamorphically grown on p-type GaN layer 106. The content of Al atoms in Ti film 114a is 0.5 atom % or less. Al film 204a is epitaxially grown on Ti film 114a. That is, the (111) crystal plane of Al film 204a is grown on the (0002) crystal plane of Ti film 114a, and the (220) crystal plane of Al film 204a is grown on the (10-10) crystal plane of Ti film 114a. The rest of the configuration is the same as that of the nitride semiconductor device described in Embodiment 1.

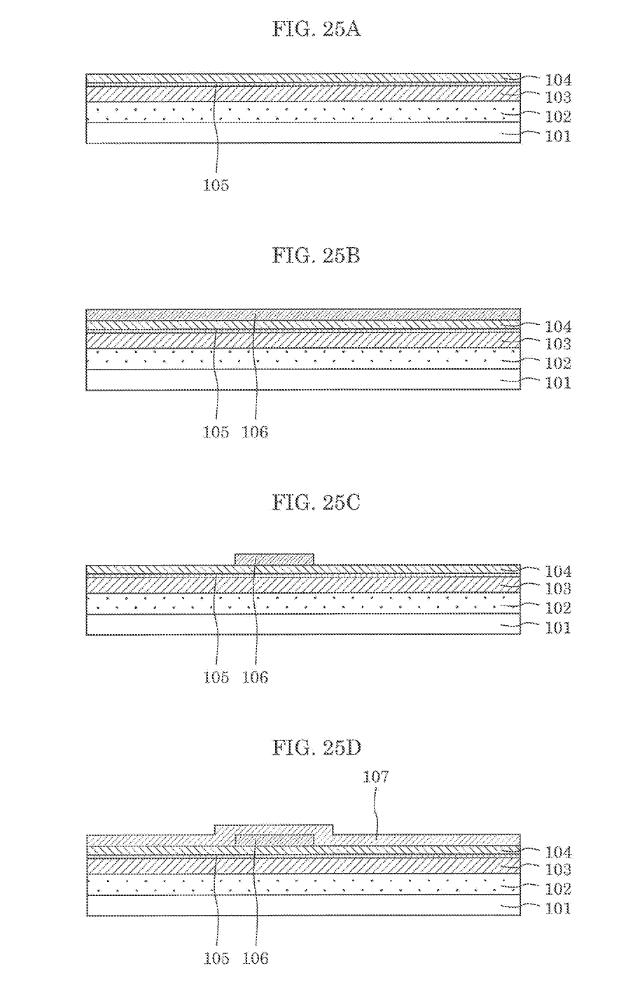

Hereinafter, a nitride semiconductor device manufacturing method according to Embodiment 3 will be described with reference to FIGS. 25A to 25D, 26A to 26C, and 27A to 27C.

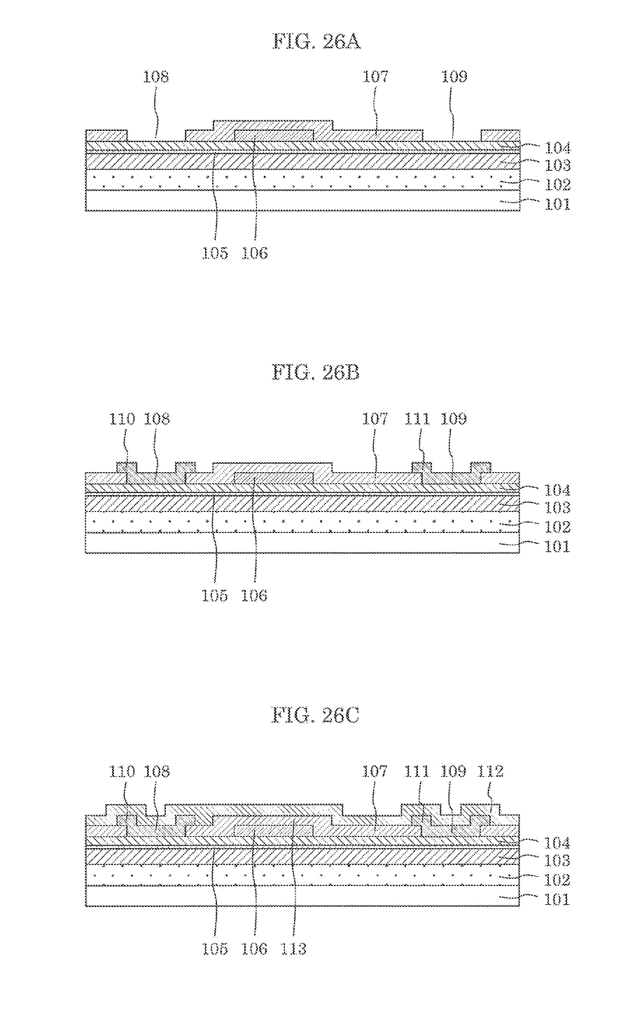

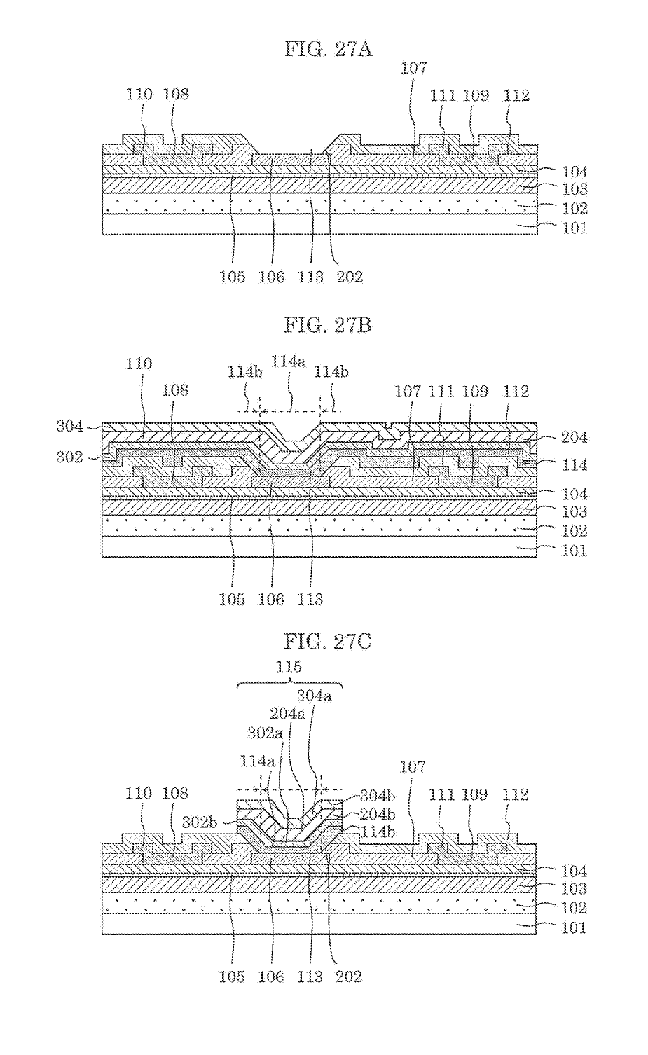

FIGS. 25A to 27C are cross-sectional views illustrating the nitride semiconductor device manufacturing method according to Embodiment 3. FIGS. 25A to 27C illustrate a sequence of steps, i.e., the step illustrated in FIG. 25D is followed by the step illustrated in FIG. 26A, and the step illustrated in FIG. 26C is followed by the step illustrated in FIG. 27A.

The steps illustrated in FIGS. 25A to 25D and 26A to 26C are the same as the steps illustrated in FIGS. 2A to 2D and 3A to 3C described in Embodiment 1, and therefore a description thereof will be omitted. The step illustrated in FIG. 27A is the same as the step illustrated in FIG. 17A described in Embodiment 2, and therefore a description thereof will be omitted.

As illustrated in FIG. 27B, Ti film 114, TiN film 302, Al film 204, and TiN film 304 are deposited in this order on the surfaces of p-type GaN layer 106 and SiN film 107 that are exposed to gate opening 113 by sputtering. Ti film 114 includes Ti film 114a that is in contact with p-type GaN layer 106 and Ti film 114b that is in contact with SiN film 112. Ti film 114a, which is in contact with p-type GaN layer 106, is coherently or metamorphically grown on p-type GaN layer 106. Al film 204a, which is in contact with TiN film 302a, is epitaxially grown on the p-type GaN layer. The epitaxial growth in this case refers to a state in which the (0002) plane of Ti film 114a and the (111) plane of Al film 204a are each parallel to the (0002) plane of the p-type GaN layer, the (10-10) plane of Ti film 114a and the (220) plane of Al film 204a are each parallel to the (10-10) plane of the p-type GaN layer, and Al film 204a does not contain crystals forming other planes, excluding irregularities of crystals in several atomic layers, such as crystal defects or dislocations. Ti film 114 and Al film 204 are separated from each other by TiN film 302. Thus, the Al content in Ti film 114 is 0.5 atom % or less. The Ti content in Al film 204 is more than 0.5 atom % because surplus Ti atoms in TiN film 304 will be diffused into Al film 204. Ti atoms in Ti film 114 will not be diffused into Al film 204.

In the last step, gate electrode 115 is formed to cover gate opening 113 by sequentially applying lithography and etching as illustrated in FIG. 27C. This completes the manufacture of the nitride semiconductor device according to the present embodiment.

Thereafter, passivation films, multilayer interconnection, and bonding pads may be formed as necessary.

Two reasons for setting acute angle 202, which is formed by the side wall of opening 113 and the surface of p-type GaN layer 106, to 45 degrees or less in the step illustrated in FIG. 27A will now be described.

The first reason is because of the crystallinity of Al film 204. Since Ti film 114b, which is in contact with SiN film 112, is neither coherently nor metamorphically grown, Al film 204b, which is in contact with Ti film 114b, is not epitaxially grown. However, if acute angle 202 formed by the side wall of opening 113 and the surface of p-type GaN layer 106 is in the range of 45 degrees to 60 degrees, crystal grains of Al film 204a, which is in contact with Ti film 114a, tend to spread in lateral directions. It is also found that, if the acute angle is 45 degrees or less, gate electrode 115 as a whole often becomes a single crystal grain.

The second reason is that, if Al film 204 is formed under bad conditions, a low Al concentration region will be formed in the longitudinal direction along the Al film, with a point of intersection between the side wall of opening 113 and the surface of p-type GaN layer 106 as an origin.

For these two reasons, acute angle 202 formed by the side wall of opening 113 and the surface of p-type GaN layer 106 needs to be 45 degrees or less in order to not impair the reliability of gate lines.

An exemplary form of deposition of Ti film 114, TiN film 302, and Al film 204 in the step illustrated in FIG. 27B will now be described. The step of depositing Ti film 114, TiN film 302, and Al film 204 may use sputtering, rather than electron-beam evaporation or resistance heating evaporation generally used in the manufacture of compound semiconductors. Moreover, the step of depositing Ti film 114, TiN film 302, and Al film 204 by sputtering may use an apparatus that includes, for example, a high-vacuum load-lock chamber, in order to avoid the entry of oxygen or other substances during a period of time from the end of deposition of Ti film 114 to the start of deposition of Al film 204. This is because, in order for Ti film 114a to be favorably coherently or metamorphically grown on p-type GaN layer 106 in the step illustrated in FIG. 27B, it is essential for Ti atoms having high, uniform kinetic energy to come flying over the surface of p-type GaN layer 106 and to be rearranged by its kinetic energy on the surface of p-type GaN layer 106. Then, it is necessary to cause Ti and N atoms having high, uniform kinetic energy to come flying over the surface of Ti film 114a, which is favorably grown coherently or metamorphically, and to allow the atoms in Ti film 114a to inherit atomic arrangement of the base layer. It is further necessary for Al atoms to come flying over the surface of TiN film 302a and to be rearranged on TiN film 302a. At this time, it is clear that the presence of impurity elements, such as oxygen, on Ti film 114a and TiN film 302a will render such rearrangement difficult.

Hereinafter, a mechanism using the Al/Ti/p-type GaN gate structure will be described, in which a metal line layer is epitaxially grown so as to exhibit high reliability even during high-temperature operations. The inventors of the present disclosure have carried out various studies in order to improve contact characteristics at the Ti/p-type GaN interface, obtain thermal stability, and form a highly reliable metal line layer thereon. As a result, they have found that the Al film formed on the TiN film, which is in a coherent or metamorphic state with respect to the p-type GaN layer, is an epitaxially grown film that has inherited the crystal information of the p-type GaN layer. Accordingly, it is possible to provide a highly reliable nitride semiconductor device whose contact resistance at the Ti/p-type GaN interface and metal line resistance will not fluctuate even when the device is used at high-temperatures.

Next is a description of results obtained by evaluating the film quality of the Al film generated by the nitride semiconductor device manufacturing method according to Embodiment 3. The evaluation primarily uses XRD. For a similar reason to that of Embodiment 1, samples are prepared by a method based on the actual manufacturing method.

Table 4 shows the conditions of each prepared sample and the half-value width in the (111) plane of the Al film. In order to study the relationship between the thickness of TiN film 302 and the crystal structure of the Al film, the following two levels of samples, namely, Samples D and E, are prepared. Sample D includes a 20-nm thick Ti film on the p-type GaN layer and a 20-nm thick TiN film on the Ti film. Sample E is includes a 20-nm thick Ti film on the p-type GaN layer and a 60-nm thick TiN film on the Ti film. Moreover, in order to clarify a difference in the crystallinity of the Al film between Ti film 114a and Ti film 114b, Sample F is prepared, which includes a 20-nm thick Ti film on SiN film 112 and a 20-nm thick TiN film on the Ti film. The above three samples all include a 200-nm thick Al film on the TiN film.

XRD allows measurement to use various methods depending on the arrangement of an X-ray light source, samples, and a detector. Thus, the inventors of the present disclosure have first carried out XRD measurement using an “out-of-plane measurement” method.

TABLE 4

| | | Structure of Metal Line Layer | | | |
|---|---|---|---|---|---|
| | | | Ti Nitride | | Rocking Curve |
| | | Ti Film | Film | Al Film | Half-Value |
| Sam- | | Thickness | Thickness | Thickness | Width (deg) |
| ple | Base Layer | (nm) | (nm) | (nm) | in Al (111) |
| D | p-type GaN | 20 | 20 | 200 | 0.35 |
| | Layer | | | | |
| E | p-type GaN | 20 | 60 | 200 | 0.45 |
| | Layer | | | | |
| F | SiN Film | 20 | 20 | 200 | 12.64 |

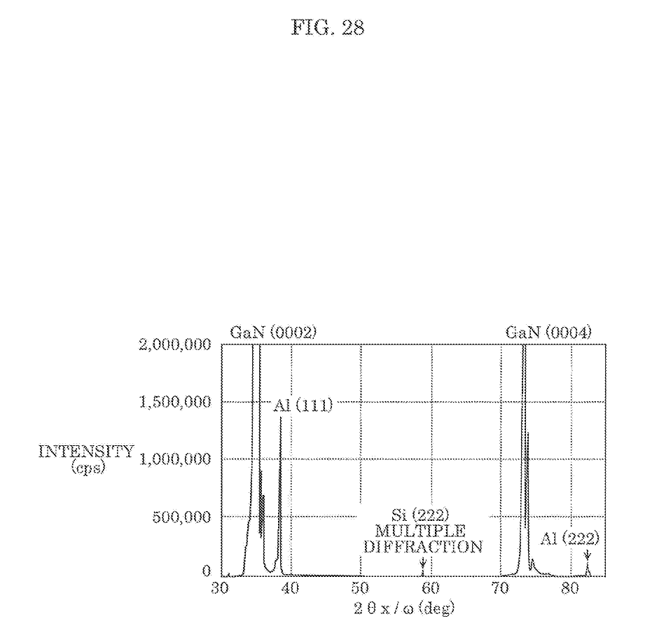

FIG. 28 illustrates an XRD spectrum obtained by out-of-plane θ-2θ measurement. More specifically, FIG. 28 illustrates the result of θ-2θ measurement for Sample D in Table 4. Except for peaks observed in the (0002) and (0004) planes of GaN, peaks are observed only at 2θ=38.472° and at 2θ=82.435°. These peaks are respectively due to diffraction in the (111) and (222) planes of Al. In the current measurement range of 2θ from 30° to 85°, diffraction in other planes, namely, (200), (220), and (311) planes of Al, is also detectable, but no corresponding peaks appear in the spectrum. This indicates that, even in the presence of the TiN film between the Ti film and the Al film, crystal information is inherited from the Tin nitride film, which is coherently or metamorphically grown on p-type GaN, to the TiN film and then to the Al film on the TiN film.

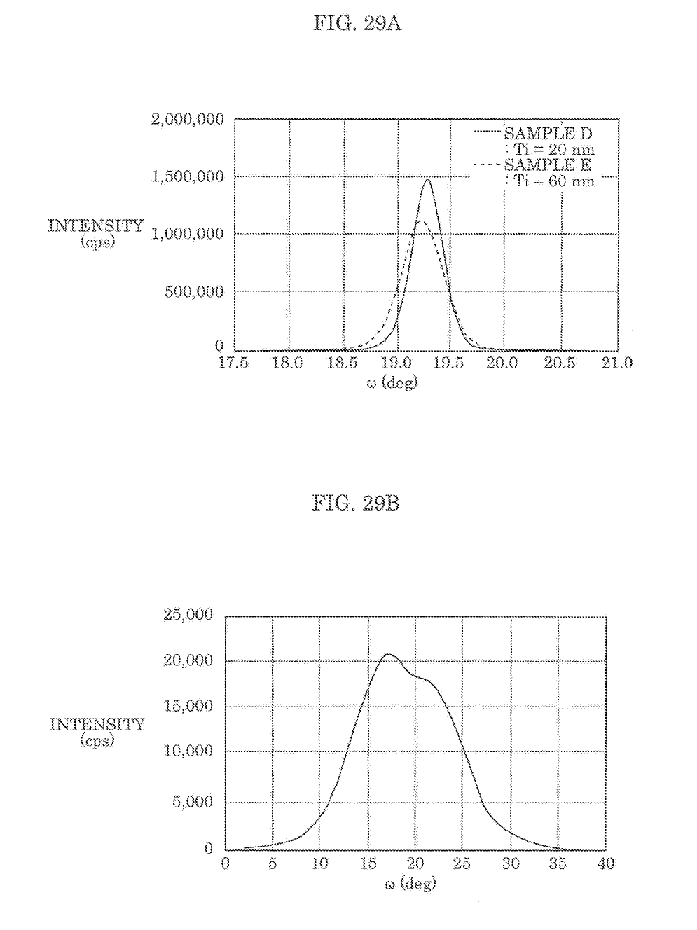

FIGS. 29A and 29B illustrate waveforms obtained by out-of-plane rocking curve measurement. More specifically, FIG. 29A shows variations in the plane orientation of the (111) plane of Al, which are measured by setting 2θ to the diffraction angle (38.5°) in the (111) plane of Al. The solid line indicates the result for Sample D in Table 4, and the broken line indicates the result for Sample E. FIG. 29B illustrates the result of measurement for Sample F in Table 4, obtained by setting 2θ to the diffraction angle (38.5°) in the (111) plane of Al.

First, the relationship between Samples D and E is focused on. As shown in Table 4, the half-value width for Sample D is 0.35°, and the half-value width for Sample E is 0.45°. This indicates that the half-value width in the Al film increases with increasing thickness of the TiN film. Moreover, the half-value widths are wider than in the case of absence of TiN shown in Table 2 of Embodiment 2. This indicates that the presence of TiN has an harmful effect on the inheritance of crystal information from p-type GaN to Al. Accordingly, the thickness of the TiN film between the Ti film and the Al film cannot be increased without limitation.

Next, the relationship between Samples D and F is focused on. Even under the same thickness condition, i.e., 20 nm, of the Ti film, if there is no coherent or metamorphic growth on the p-type GaN layer, the half-value width in the (111) plane of the Al film for Sample C is 12.64° is an order of magnitude greater than the values for the other samples. This indicates that Al has completely different crystallinity.

Next, XRD measurement is conducted using an “in-plane measurement” method. The “in-plane measurement” method is the same as that of Embodiment 1.

In the present embodiment, a samples is installed so that the (10-10) plane of GaN becomes orthogonal to the incident X ray.

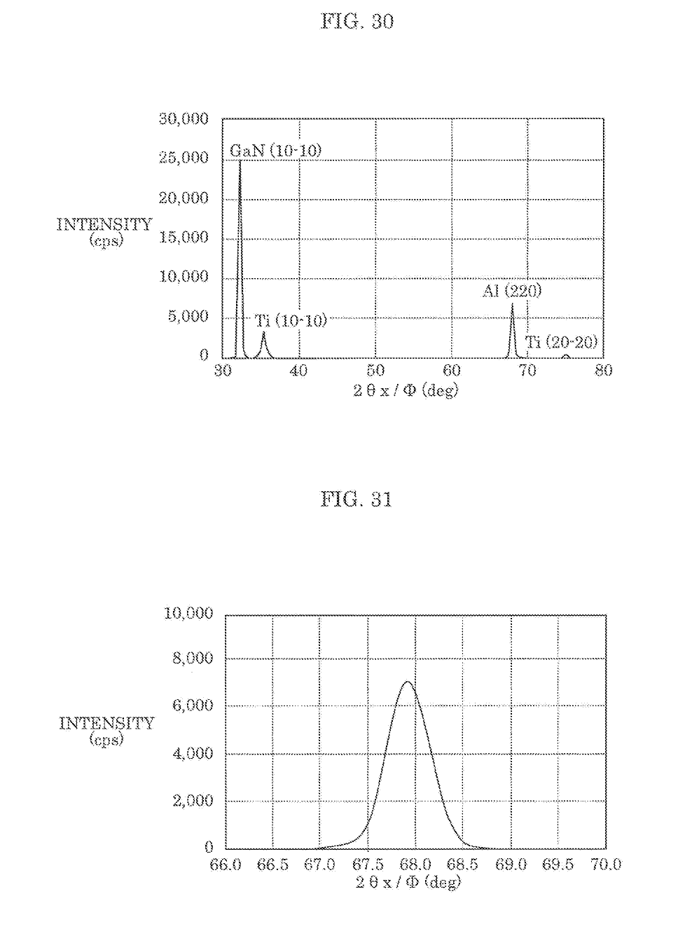

FIG. 30 illustrates an XRD spectrum obtained by in-plane 2θ measurement. More specifically, FIG. 30 illustrates the result of θ-2θ measurement for Sample D in Table 4. Except for peaks due to diffraction in GaN and the Ti film, a peak is only observed at 2θ=65. 133°. This is due to diffraction in the (220) plane of Al. In the current measurement range of 2θ from 30° to 80°, diffraction in other planes, namely, (111), (200), and (311) planes of Al, is also detectable, but no corresponding peaks appear in the spectrum.

The XRD spectrum for this sample is measured by fixing the rotation angle (θ) of the detector in accordance with specific diffraction and then changing only the tilt angle (ω) of the sample. This is a scan method called a “rocking curve” method and can measure variations in the plane orientation of a specific crystal plane included in a film.

FIG. 31 illustrates a waveform obtained by in-plane rocking curve measurement. More specifically, FIG. 31 shows variations in the plane orientation of the (220) plane of Al, which are measured by setting 2θ to the diffraction angle (67.8°) in the (220) plane of Al. That is, FIG. 31 shows the result for the (220) plane of Al of Sample D in Table 4. The half-value width in the (220) plane of Al of Sample D is 0.42°. This indicates that the presence of the TiN film between the Ti film and the Al film does not degrade crystallinity so much.

A desired thickness of TiN film 302a will now be described. The thickness of TiN film 302a may be set to 20 nm or more. This is because the separation of Ti film 114 and Al film 204 by the TiN film will become insufficient if the thickness of the TiN film is less than 20 nm. However, increasing the thickness of TiN film 302a will inhibit the Al film from inheriting the crystal information of the p-type GaN layer. Thus, the total thickness of Ti film 114a and TiN film 302a may be 60 nm or less. This is because, although it has been ascertained that the Al film will be grown epitaxially until the total thickness of Ti film 114a and TiN film 302a reaches 80 nm, local problems due to degradation of the crystallinity of the metal line layer may adversely affect the reliability of the nitride semiconductor device. The TiN film with this thickness can reliably improve contact characteristics at the Ti/p-type GaN interface, and at the same time, can achieve highly reliable lines with a single-crystal Al film and suppress fluctuations in contact characteristics and wiring resistance when the nitride semiconductor device operates at high temperatures. While the Al film in the present embodiment has a thickness of 200 nm, the thickness of the Al film may be several micrometers.

According to the present embodiment, an FET capable of high-speed switching can be achieved by reducing the resistance at the contact between the p-type nitride semiconductor layer and the metal line layer.

The present embodiment can also provide a new power switching FET by making the metal line layer of a material other than previous metals so as to considerably reduce the manufacturing cost, and also by making the metal line layer into a single crystal so as to achieve high reliability.

While the p-type nitride semiconductor layer according to Embodiments 1 to 3 described above is made of GaN, the p-type nitride semiconductor layer may be a p-type AlInGaN layer having an Al composition ratio of approximately 10%, or may have a stacked structure of a p-type AlInGaN layer having an Al composition ratio of approximately 10% and a p-type GaN layer. For example, the p-type nitride semiconductor layer may be a p-type AlInGaN layer with an Al composition ratio of approximately 10%, or may have a stacked structure of a p-type AlInGaN layer and a p-type GaN layer. The i-type GaN layer and the i-type AlGaN layer may be of n-type. While an example of the nitride semiconductor device using a Si substrate is given in the present embodiment, the substrate may be made of other materials such as sapphire, SiC, and GaN that enable the formation of a nitride semiconductor layer.

### Embodiment 4

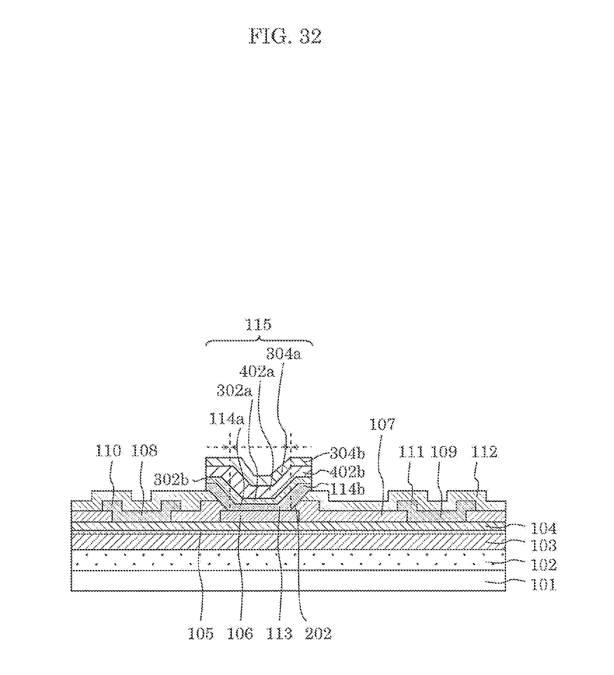

FIG. 32 is a cross-sectional view of a nitride semiconductor device according to Embodiment 4. As illustrated n FIG. 32, the nitride semiconductor device according to the present embodiment includes, for example, substrate 101 made of Si, buffer layer 102 having a thickness of 2 μm and having a stacked structure of a plurality of layers including AlN and AlGaN, undoped (i-type) GaN layer 103 having a thickness of 2 μm, and i-type AlGaN layer 104 having a thickness of 25 nm and an Al composition ratio of 15%, in such a manner that buffer layer 102, i-type GaN layer 103, and i-type AlGaN layer 104 are formed on substrate 101. Two dimensional electron gas 105 is generated at the heterointerface between i-type AlGaN layer 104 and i-type GaN layer 103. The nitride semiconductor device according to the present embodiment also includes p-type GaN layer 106 having a thickness of 200 nm and being processed in a predetermined shape on the surface of i-type AlGaN layer 104. Here, p-type GaN layer 106 is doped with Mg at a concentration of approximately 5×10¹⁹ cm⁻³.

The nitride semiconductor device according to the present embodiment further includes SiN film 107 on the surfaces of i-type AlGaN layer 104 and p-type GaN layer 106. The Si content in SiN film 107 is approximately 50%. This ratio is higher than the stoichiometric mixture ratio (43%).

SiN film 107 has source opening 108 and drain opening 109 that reach i-type AlGaN layer 104 and in which source electrode 110 and drain electrode 111 are respectively provided to cover the openings. Source electrode 110 and drain electrode 111 have a structure in which a Ti film and an Al film are sequentially stacked on top of each other, and establish electrical contact with two-dimensional electron gas 105 generated at the heterointerface between i-type AlGaN layer 104 and i-type GaN layer 103.

Another SiN film 112 is formed on the surfaces of SiN film 107, source electrode 110, and drain electrode 111. As in the case of SiN film 107, the Si content in SiN film 112 is approximately 50%.

SiN films 107 and 112 have gate opening 113 that reaches p-type GaN layer 106, and acute angle 202 formed by the side wall of this opening and the surface of p-type GaN layer 106 is 45 degrees or less. Gate electrode 115 is formed to cover gate opening 113. Gate electrode 115 includes Ti film 114a that is in contact with p-type GaN layer 106, TiN film 302a that is in contact with Ti film 114a, copper (Cu) film 402a that is in contact with TiN film 302a, TiN film 304a that is in contact with Cu film 402a, Ti film 114b that is in contact with SiN film 112, TiN film 302b that is in contact with Ti film 114b, Cu film 402b that is in contact with TiN film 302b, and TiN film 304b that is in contact with Cu film 402b. Ti films 114a and 114b both have a thickness of 10 nm. TiN films 302a and 302b both have a thickness of 20 nm. Cu films 402a and 402b have a thickness of 400 nm or more. Ti film 114a is coherently or metamorphically grown on p-type GaN layer 106. The content of Cu atoms in Ti film 114a is 0.5 atom % or less. Cu film 402a is epitaxially grown on Ti film 114a. That is, the (111) crystal plane of Al film 204a is grown on the (0002) crystal plane of Ti film 114a, and the (220) crystal plane of Al film 204a is grown on the (10-10) crystal plane of Ti film 114a. The rest of the configuration is the same as that of the nitride semiconductor device according to Embodiment 1.

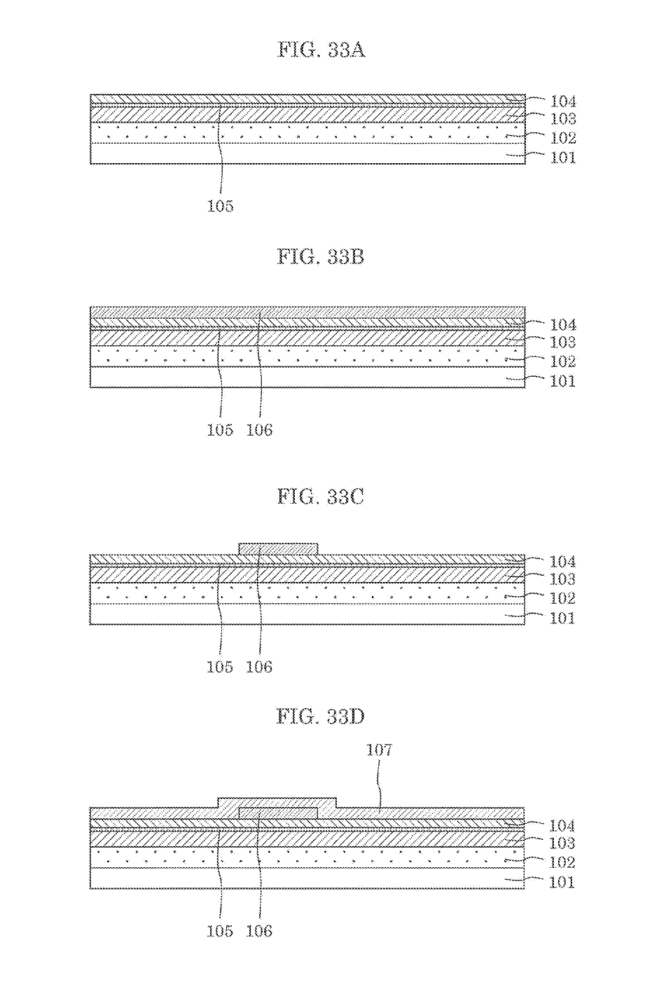

Hereinafter, a nitride semiconductor device manufacturing method according to Embodiment 4 will be described with reference to FIGS. 33A to 33D, 34A to 34C, and 35A to 35C.

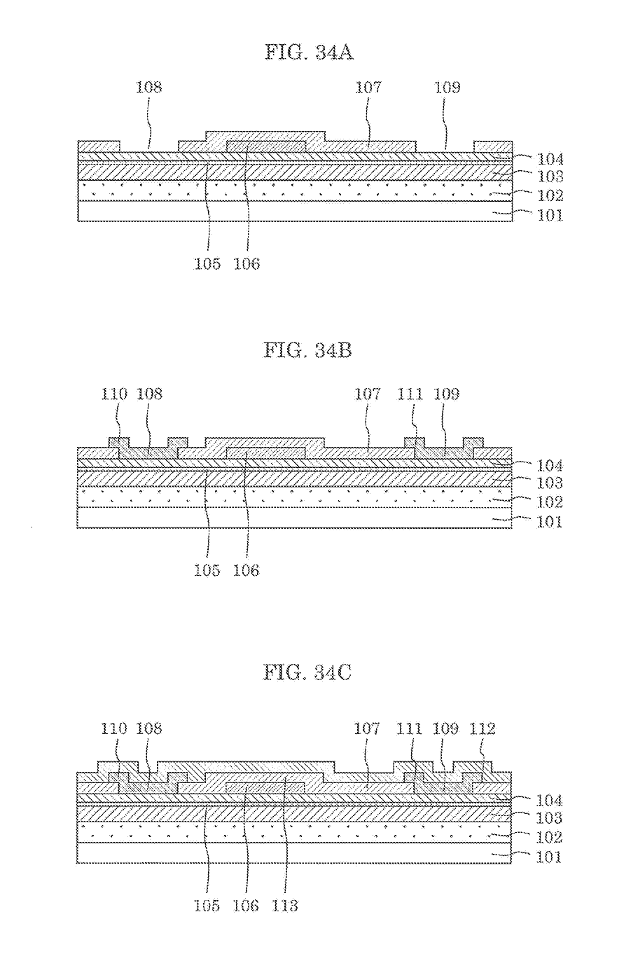

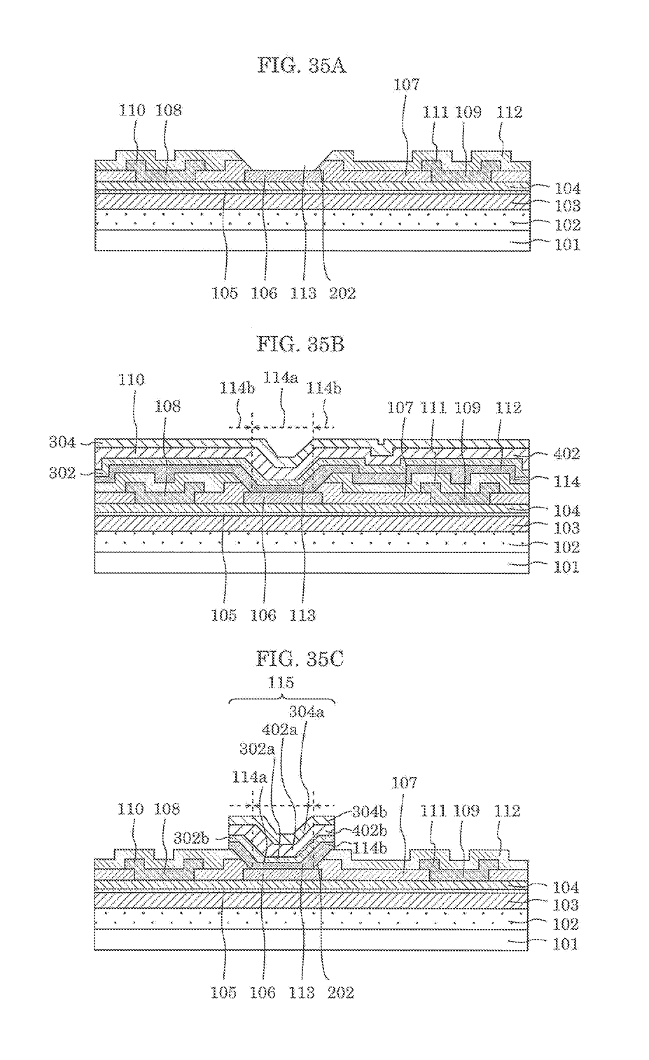

FIGS. 33A to 33D, 34A to 34C, and 35A to 35C are cross-sectional views illustrating the nitride semiconductor device manufacturing method according to Embodiment 4. FIGS. 33A to 33D, 34A to 34C, and 35A to 35C illustrate a sequence of steps, i.e., the step illustrated in FIG. 33D is followed by the step illustrated in FIG. 34A, and the step illustrated in FIG. 34C is followed by the step illustrated in FIG. 35A.

The steps illustrated in FIGS. 33A to 33D and 34A to 34C are the same as the steps illustrated in FIGS. 2A to 2D and 3A to 3C described in Embodiment 1, and therefore a description thereof will be omitted. The step illustrated in FIG. 35A is the same as the step illustrated in FIG. 17A described in Embodiment 2, and therefore a description thereof will be omitted.

As illustrated in FIG. 35B, Ti film 114, TiN film 302, Cu film 402, and TiN film 304 are deposited in this order by sputtering on the surfaces of p-type GaN layer 106 and SiN film 107 that are exposed to gate opening 113. Ti film 114 includes Ti film 114a that is in contact with p-type GaN layer 106, and Ti film 114b that is in contact with SiN film 112. Ti film 114a is coherently or metamorphically grown on p-type GaN layer 106. Cu film 402a, which is in contact with TiN film 302a, is epitaxially grown on the p-type GaN layer. The epitaxial growth in this case refers to a state in which the (0002) plane of Ti film 114a and the (111) plane of Cu film 402a are each parallel to the (0002) plane of the p-type GaN layer, the (10-10) plane of Ti film 114a and the (220) plane of Cu film 402a are each parallel to the (10-10) plane of the p-type GaN layer, and Cu film 402a does not contain crystals forming other planes, excluding irregularities of crystals in several atomic layers, such as crystal defects or dislocations. Ti film 114 and Cu film 402 are separated from each other by TiN film 302. Thus, the Cu content in Ti film 114 is 0.5 atom % or less. The Ti content in Cu film 402 is more than 0.5 atom % because surplus Ti atoms in TiN film 304 will be diffused into Cu film 402. Ti atoms in Ti film 114 will not be diffused into Cu film 402.

In the last step, gate electrode 115 is formed to cover gate opening 113 by sequentially applying lithography and etching as illustrated in FIG. 35C. This completes the manufacture of the nitride semiconductor device according to the present embodiment.

Thereafter, passivation films, multilayer interconnection, and bonding pads may be formed as necessary.

Two reasons for setting acute angle 202, which is formed by the side wall of opening 113 and the surface of p-type GaN layer 106, to 45 degrees or less in the step illustrated in FIG. 35A will now be described.

The first reason is because of the crystallinity of Al film 204. Since Ti film 114b, which is in contact with SiN film 112, is neither coherently nor metamorphically grown, Cu film 402b, which is in contact with Ti film 114b, is not epitaxially grown. However, if acute angle 202 formed by the side wall of opening 113 and the surface of p-type GaN layer 106 is in the range of 45 degrees to 60 degrees, crystal grains of Cu film 402a, which is in contact with Ti film 114a, tend to spread in lateral directions. It is also found that, if the angle is 45 degrees or less, gate electrode 115 as a whole often becomes a single crystal grain.

The second reason is that, if Cu film 402 is formed under bad conditions, a low Cu concentration region will be formed in the longitudinal direction along the Cu film, with a point of intersection between the side wall of opening 113 and the surface of p-type GaN layer 106 as an origin.

For these two reasons, acute angle 202 formed by the side wall of opening 113 and the surface of p-type GaN layer 106 needs to be 45 degrees or less in order to not impair the reliability of gate lines.

An exemplary form of deposition of Ti film 114, TiN film 302, and Cu film 402 in the step illustrated in FIG. 35B will now be described. The step of depositing Ti film 114, TiN film 302, and Cu film 402 may use sputtering, rather than electron-beam evaporation or resistance heating evaporation generally used in the manufacture of compound semiconductors. Moreover, the step of depositing Ti film 114, TiN film 302, and Cu film 402 by sputtering may use an apparatus that includes, for example, a high-vacuum load-lock chamber, in order to avoid the entry of oxygen or other substances during a period of time from the end of deposition of Ti film 114 to the start of deposition of Cu film 402. This is because, in order for Ti film 14a to be favorably grown coherently or metamorphically on p-type GaN layer 106 in the step illustrated in FIG. 35B, it is essential for Ti atoms having high, uniform kinetic energy to come flying over the surface of p-type GaN layer 106 and to be rearranged by its kinetic energy on the surface of p-type GaN layer 106. Then, it is necessary to cause Ti and nitrogen (N) atoms having high, uniform kinetic energy to come flying over the surface of Ti film 114a, which is favorably grown coherently or metamorphically, and to allow atoms in Ti film 114a to inherit atomic arrangement of the base layer. It is further necessary for Cu atoms to come flying over the surface of TiN film 302a and to be rearranged on TiN film 302a. At this time, it is clear that the presence of impurity elements, such as oxygen, on Ti film 114a and TiN film 302a will render such rearrangement difficult.

Hereinafter, a mechanism using the Cu/TiN/p-type GaN gate structure will be described, in which a metal line layer is epitaxially grown so as to exhibit high reliability even during high-temperature operations. The inventors of the present disclosure have carried out various studies in order to improve contact characteristics at the Ti/p-type GaN interface, obtain thermal stability, and form a highly reliable metal line layer thereon. As a result, they have found that the Cu film formed on the TiN film on Ti, which is in a coherent or metamorphic state with respect to the p-type GaN layer, is an epitaxially grown film that has inherited the crystal information of the p-type GaN layer. Accordingly, it is possible to provide a highly reliable nitride semiconductor device whose contact resistance at the Ti/p-type GaN interface and metal line resistance will not fluctuate even when the nitride semiconductor device is used at high temperatures.

While Embodiment 4 describes an exemplary case in which the metal line layer is structured by sequentially forming Ti film 114, TiN film 302, Cu film 402, and TiN film 304 in this order on the p-type GaN layer, TiN film 302 may be omitted as necessary. In this case, TiN film 304 may also be replaced by Ti film 206.

While the metal line layer according to Embodiment 4 is formed by lithography and dry etching after deposition of the metal film, the metal film may be deposited after lithography and a vapor deposition lift-off technique employing wet etching may be used.

While the p-type nitride semiconductor layer according to Embodiment 4 is made of GaN, the p-type nitride semiconductor layer may be a p-type AlInGaN layer having an Al composition ratio that is equivalent to or less than that of the i-type AlGaN layer formed under the p-type nitride semiconductor layer. For example, the p-type nitride semiconductor layer may be a p-type AlInGaN layer having an Al composition ratio of 10%, or may have a stacked structure of a p-type AlInGaN layer having an Al composition ratio of 10% and a p-type GaN layer.

The i-type GaN layer and the i-type AlGaN layer may be of n type.

### OTHER EMBODIMENTS

The nitride semiconductor device according to the present disclosure is not limited to the examples described in Embodiments 1 to 4. The present disclosure also includes other embodiments that are achieved by a combination of any constituent elements described in Embodiments 1 to 4, variations that are obtained by making various modifications conceivable by a person skilled in the art to the above-described embodiments within departing from the scope of the present disclosure, and various devices that are equipped with any of the nitride semiconductor devices according to the above-described embodiments.

While the above-described embodiments show examples of semiconductor devices using a Si substrate, the substrate may be made of other materials such as sapphire, SiC, or GaN that enable the formation of a nitride semiconductor layer.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The nitride semiconductor device according to the present disclosure achieves low power consumption and reduces gate leakage current to such a level that will not cause any problems in practice. Thus, this nitride semiconductor device

is useful as a power switching element for use in devices such as inverters or power supply circuits.

What is claimed is:

1. A nitride semiconductor device comprising:
a substrate;
a semiconductor layer formed on a main surface of the substrate and made of AlₓIn_{y}Ga_{1-x-y}N containing a p-type impurity, where 0≦X<1 and 0≦Y<1; and
a titanium (Ti) layer formed on the semiconductor layer,
wherein the Ti layer is in a coherent or metamorphic state with respect to the semiconductor layer.

2. The nitride semiconductor device according to claim 1,
wherein a (0002) crystal plane of the Ti layer is parallel to and oriented in a same direction as a (0002) crystal plane of the semiconductor layer.

3. The nitride semiconductor device according to claim 2,
wherein a (10-10) crystal plane of the Ti layer is parallel to and oriented in a same direction as a (10-10) crystal plane of the semiconductor layer.

4. The nitride semiconductor device according to claim 3,
wherein the Ti layer has a thickness of 5 nm or more.

5. The nitride semiconductor device according to claim 1, further comprising
a metal line layer formed on the Ti layer and made primarily of aluminum,
wherein a portion of the Ti layer that is within a fixed distance from an interface between the semiconductor layer and the Ti layer is not alloyed with the metal line layer.

6. The nitride semiconductor device according to claim 5,
wherein the fixed distance is 5 nm or more.

7. The nitride semiconductor device according to claim 5,
wherein a (111) crystal plane of the metal line layer is parallel to and oriented in a same direction as a (0002) crystal plane of the Ti layer.

8. The nitride semiconductor device according to claim 7,
wherein a (220) crystal plane of the metal line layer is parallel to and oriented in a same direction as a (10-10) crystal plane of the Ti layer.

9. The nitride semiconductor device according to claim 8,
wherein the Ti layer has a thickness of 60 nm or less.

10. The nitride semiconductor device according to claim 5, further comprising
a titanium nitride (TiN) layer between the Ti layer and the metal line layer.

11. The nitride semiconductor device according to claim 10,
wherein the TiN layer has a thickness of 20 nm or more.

12. The nitride semiconductor device according to claim 11,
wherein a total thickness of the Ti layer and the TiN layer is 60 nm or less.

13. The nitride semiconductor device according to claim 5, further comprising
an insulating layer between the semiconductor layer and the Ti layer,
wherein the insulating layer has a through opening, and
the Ti layer is in contact with the semiconductor layer at a lower surface of the through opening.

14. The nitride semiconductor device according to claim 13,
wherein the through opening has an open lower surface, and an open upper surface that has a larger opening area than the open lower surface, and
an acute angle formed by a side wall of the through opening and the semiconductor layer is 45 degrees or less.

15. The nitride semiconductor device according to claim 5, further comprising:
a channel layer formed on the substrate and made of a nitride semiconductor;
a barrier layer formed on the channel layer and made of a nitride semiconductor having a larger band gap than the channel layer;
a gate electrode formed on a lower surface of the channel layer; and
a source electrode and a drain electrode that are formed on each side of the gate electrode and spaced from the gate electrode,
wherein the semiconductor layer is used as the gate electrode.

16. The nitride semiconductor device according to claim 1, further comprising
a metal line layer formed on the Ti layer and made primarily of copper,
wherein a portion of the Ti layer that is within a fixed distance from an interface between the semiconductor layer and the Ti layer is not alloyed with the metal line layer.

17. The nitride semiconductor device according to claim 16,
wherein a (111) crystal plane of the metal line layer is parallel to and oriented in a same direction as a (0002) crystal plane of the Ti layer.

18. The nitride semiconductor device according to claim 17,
wherein a (220) crystal plane of the metal line layer is parallel to and oriented in a same direction as a (10-10) crystal plane of the Ti layer.

19. The nitride semiconductor device according to claim 16, further comprising
a titanium nitride layer between the Ti layer and the metal line layer.

20. The nitride semiconductor device according to claim 16, further comprising
an insulating layer between the semiconductor layer and the Ti layer,
wherein the insulating layer has a through opening, and
the Ti layer is in contact with the semiconductor layer at a lower surface of the through opening.
